(19) United States
(12) Patent Application Publication
(10) Pub. No.: US 2010/0218819 A1
(43) Pub. Date: Sep. 2, 2010

(54) SEMICONDUCTOR OPTOELECTRONIC DEVICES AND METHODS FOR MAKING SEMICONDUCTOR OPTOELECTRONIC DEVICES

(75) Inventors: Corrie Farmer, Glasgow (GB); Colin Stanley, Glasgow (GB)

Correspondence Address: Leason Ellis LLP, 81 Main Street, Suite 503, White Plains, NY, 10601, US

(73) Assignee: The University Court of the University of Glasgow, Glasgow (GB)

(21) Appl. No.: 12/681,390

(22) PCT Filed: Oct. 6, 2008
(86) PCT No.: PCT/GB08/03373

§ 371 Date: Apr. 2, 2010

(30) Foreign Application Priority Data
Oct. 5, 2007 (GB) 0719554.

(51) Int. Cl. H01L 27/142; H01L 31/0216; H01L 33/48; H01L 31/18; H01L 21/302

(52) U.S. Cl. 136/256; 257/434; 257/98; 438/65; 438/27; 257/E31.119; 257/E33.06; 257/E27.123; 257/E21.214

(57) ABSTRACT

A semiconductor-based optoelectronic device such as a solar cell has an n-type layer and a p-type layer, together forming a p-n junction. Contact regions are formed on the device, with light-receiving regions between contact regions. A window layer is formed over the n-type layer or the p-type layer at the light-receiving region, the window layer promoting reduced carrier recombination at the surface of the n-type or p-type layer, and/or reflection of minority carriers in the n-type or p-type layer towards the p-n junction. The device has a window protection layer formed over the window layer, the window protection layer providing protection from degradation of the window layer during manufacture and/or operation of the device. For GaAs-based devices the window layer may be Al0.9Ga0.1As and the window protection layer may be GaAs. Additionally, an AlAs etch stop layer may be provided over the window protection layer.

### FIELD OF THE INVENTION

The present invention relates to semiconductor optoelectronic devices and methods for making semiconductor optoelectronic devices. The invention is of particular, but not exclusive, interest to semiconductor photovoltaic devices.

### BACKGROUND TO THE INVENTION AND RELATED ART

Semiconductor photovoltaic cells are known for use in renewable power generation, both for terrestrial and non-terrestrial applications.

Many optoelectronic devices include a window layer, through which ‘useful photons’ travel, between light absorbing or light-emitting layers and the exterior of the opto-electronic device. These optoelectronic devices include, for example, photodiodes (including solar cells), phototransistors, light-emitting diodes, and vertical-cavity surface-emitting lasers.

For a photodiode, it is possible to define ‘useful photons’ as those photons incident on the device that have photon energy, Eₚₕₒₜₒₙ=hf=hc/λ, within a certain range of energies that the device is designed to convert into an electrical current (or into an electrical potential difference). In a light-emitting device, it is possible to define ‘useful photons’ as those photons that are generated by the light-emitting layers of the device, and which produce useful output. In both cases, it is possible to define ‘useful photons’ as those which contribute to the external quantum efficiency of the device.

For example, the solar spectrum (see FIG. 1) consists of light that has usable energy in the photon range of 0.4<E_{hf}<4 eV, so solar cells are generally designed to respond to light within this spectral range (or are optimized for a part of this range). In known solar cells that rely on single-photon absorption processes, the lower energy bound for useful photons depends on the bandgap energy of the photovoltaic materials used in the device. It is approximately equal to the bandgap energy of the photovoltaic material with the lowest bandgap (for example, for GaAs this value is about 1.424 eV (at 297 K) in the case of a GaAs single-junction cell), as photons with energy below that of the bandgap have a very low probability of being absorbed in the photovoltaic material (a single photon has insufficient energy to excite an electron from the valence band to the conduction band).

A typical simple photovoltaic (or indeed light-emitting) device consists of a p-n (or p-i-n) junction semiconductor diode in which the front surface metallization is discontinuous in order to let light pass in (or out) of the active device layers. In a photovoltaic device, electrons and holes that are generated by the absorption of useful photons in the emitter and base regions, and that are separated by the built-in electric field that exists at the p-n junction, give rise to a potential difference between the output terminals of the diode. In an electrically pumped light emitting device, the application of a potential difference (forward bias) between the output terminals of the diode injects charge carriers separately, which then give rise to light-emission when the electrons and holes recombine at, or close to the p-n junction.

The absorption coefficient of GaAs (see FIG. 3) is large at photon energies above the bandgap energy of GaAs (E_{g} of about 1.424 eV). Therefore a thickness of about 4 μm of GaAs semiconductor is sufficient to absorb the vast majority of all of the photons that enter the cell with photon energy Eₚₕₒₜₒₙ>1.424 eV.

FIG. 2a shows a schematic cross section of a typical single-junction heteroface solar cell based on GaAs. It is to be noted that this is the starting point of the present invention, but it is not published prior art per se. FIG. 2b shows the energy band diagram (under thermal equilibrium) calculated for the structure of FIG. 2a using 1D Poisson Solver available from http://www.nd.edu/˜gsnider/ (accessed 1 Oct. 2007) as freeware. This program is for calculating energy band diagrams and free carrier distributions for semiconductor structures. It solves one-dimensional Poisson and Schrödinger equations self-consistently. It was written by Professor Gregory Snider, Department of Electrical Engineering, University of Notre Dame, Notre Dame, Ind. 46556, USA.

An un-passivated semiconductor surface (e.g. an un-passivated emitter layer) generally exhibits a high density of surface states and a corresponding high value of recombination velocity. Charge carriers generated close to such a surface have a high probability of being captured and recombining non-radiatively, thereby degrading the overall quantum efficiency of the device. As the optical absorption coefficient α (E_{hf}) increases with photon energy above the bandgap energy, useful photons with high photon energies (e.g. blue light) are absorbed much closer to the front surface of the semiconductor (while lower energy photons (e.g. corresponding to red light) are absorbed deeper in the device). For this reason, recombination at the emitter front surface generally leads to a more pronounced degradation in the high-energy (or ‘blue’) quantum efficiency of the device, as compared to the quantum efficiency at lower ('red') photon energies.

It is known to passivate the front surface (e.g. emitter) of the device with a layer, often referred to as the ‘window’ layer. The window layer:
a) forms an interface with the emitter that exhibits a low recombination velocity
b) is highly transparent to ‘useful photons’
c) presents a potential energy barrier to the minority carriers in the emitter layer (i.e. acts as a ‘minority carrier mirror’, effectively reflecting the minority carriers back into the emitter), in order to suppress their transport through the window layer
d) presents a minimal potential energy barrier and a minimal electrical resistance to majority carriers in the emitter, allowing their transport through the window layer

In a semiconductor device, it is an aim to satisfy these criteria by using a window layer that is composed of a compatible semiconductor (i.e. a lattice-matched or a coherently strained (pseudo-morphic) semiconductor layer grown to provide coherent interfaces with low surface recombination) that possesses a bandgap energy greater than that of the underlying photovoltaic layers and greater than that of the photon energy of all (or the majority) of the useful photons passing through it.

Examples of GaAs-based photovoltaic devices incorporating window layers and antireflective coatings are shown in U.S. Pat. No. 6,150,603 and U.S. Pat. No. 7,119,271.

A solar cell design with a thin (about 7 nm thick) Al_{0.85}Ga_{0.15}As window layer, covered by an ultrathin (about 5-6 nm thick) p⁺-GaAs cap layer was demonstrated by Milanova et al [Reference 37]. The authors of that paper observed improved blue response over cells without the p⁺-GaAs cap layer. The motivation given for using the ultra-thin p⁺-GaAs cap layer was to provide a highly-doped surface layer to reduce carrier recombination at the surface. In the view the present inventors, this highly doped cap layer is also required to facilitate the formation of low resistance ohmic contacts to it. It is considered that simply increasing the doping level in this way will not in itself reduce the surface recombination velocity.

A photovoltaic cell (not solar cell) design with a 30 nm-thick Al_{0.85}Ga_{0.15}As window layer, covered by a thick p⁺⁺-Al_{0.3}Ga_{0.7}As layer was demonstrated by van Riesen et al in Reference 38. The motivation for the additional 400 nm-thick p⁺⁺-Al_{0.3}Ga_{0.7}As over-layer was to enhance lateral conduction between grid fingers. The cell was designed as a photovoltaic power converter for a high power laser beam light source.

U.S. Pat. No. 4,544,799 discloses a solar cell design based on GaAs on which is formed a two-part window layer. In contact with the GaAs is a layer of gallium arsenide phosphide. In contact with the layer of gallium arsenide phosphide is a layer of gallium phosphide. The thickness of the gallium phosphide layer is suggested to be less than 1.0 μm.

The present inventors have identified problems with known devices, in particular related to the window layer and its effects on subsequent processing and operation of devices. The specific identification of these problems is considered to be part of the present invention, and so is described under the heading “Summary of the invention” below.

### SUMMARY OF THE INVENTION

In the case of a heteroface solar cell, the window layer typically requires a bandgap energy equal to or greater than about 4 eV, if it is to avoid absorbing useful photons from the solar spectrum. Although semiconductor materials do exist with bandgap energy of greater than 4 eV (e.g. AlN) they are not generally compatible with the semiconductors typically used as photovoltaic layers (e.g. GaAs, AlₓGa₁₋ₓAs, (AlₓGa₁₋ₓ)_{0.51}In_{0.49}P, Ge). Therefore, a compromise is typically made in the performance of the window, and a window layer material is selected that will best match the requirements, from a list of materials that are known to be compatible with the underlying photovoltaic layer(s).

In semiconductor physics, the energy bandgap E_{g} is equal to the difference in energy between the point of minimum energy in the conduction band and the point of maximum energy in the valence band. A direct bandgap means that the minimum of the conduction band lies directly above the maximum of the valence band in momentum space (k-space). The point in k-space where the valence band is at a maximum is referred to as the Γ-point. At the Γ-point, we define the energy difference between the conduction and valence bands as E_{Γ}. In a direct semiconductor, E_{g}=E_{Γ}.

In contrast, an indirect bandgap is an energy bandgap in which the minimum energy in the conduction band is shifted by a k-vector relative to the valence band, and E_{g}<E_{Γ}. The k-vector difference represents a difference in momentum. In an indirect-bandgap semiconductor, an inter-band absorption transition between the maximum in the valence band and the minimum in the conduction band requires the interaction of one or more phonons with an electron. The phonon interaction is necessary in order to conserve both energy and momentum in the transition. For this interaction, the probability is relatively low, and consequently the absorption/emission of photons with energy E_{g}<Eₚₕₒₜₒₙ<E_{Γ} is still relatively low. However, direct transitions become much more likely at higher photon energies, e.g. Eₚₕₒₜₒₙ>E_{Γ}, where absorption rises more steeply.

Typically, compound semiconductors that have a high aluminium mole fraction have an indirect bandgap. For example, at 298 K, AlₓGa₁₋ₓAs has an indirect bandgap when the aluminium mole fraction exceeds x=0.45, in which case the interband transition with the lowest available transition energy is from the top of the valence band (at the Γ-point) to the bottom of the X-valley (at the X-point), where the energy bandgap is E_{g}=E_{X}. Similarly, (AlₓGa₁₋ₓ)_{0.51} In_{0.49}P has an indirect bandgap for x>0.55 [see Reference 1]. FIG. 3 shows a graph of solar photon flux and the absorption coefficient of bulk AlₓGa₁₋ₓAs with Al mole fraction x=0.19, 0.80, 1.00 [from Reference 5]. FIG. 3 shows that, although the bandgap energy of Al_{0.8}Ga_{0.2}As is about 2.1 eV, the absorption coefficient is low until the photon energy becomes comparable to E_{Γ} of about 2.6 eV.

For this reason, when we consider which semiconductor materials are the most appropriate to use as a window layer, we concentrate on the energy bandgap (at 298 K) at the Γ-point, E_{Γ} as a figure of merit. Unless otherwise stated, references to bandgap energy in the present disclosure are preferably references to the bandgap energy at the Γ-point.

We take a GaAs heteroface solar cell as an example, where GaAs forms the photovoltaic emitter and base layers, and AlₓGa₁₋ₓAs is used as the window layer. Since the lattice constants of AlAs and GaAs are almost identical (within 0.1%) AlₓGa₁₋ₓAs with any aluminium fraction x is deemed to be compatible with a GaAs substrate. Indeed, layers of AlₓGa₁₋ₓAs (0<x<1) may be grown epitaxially on GaAs with excellent interfaces [see References 2,3] and a coherent length (the thickness of material that may be grown before strain relaxation occurs) of several hundreds of nanometers can be achieved when growing pure AlAs [see Reference 4]. Another material system that is lattice-matched with GaAs is (AlₓGa₁₋ₓ)_{0.51}In_{0.49}P (0<x<1).

Ideally, the window layer will exhibit very low optical absorption for all (or the majority) of useful photons. From FIG. 3, it can be seen that AlₓGa₁₋ₓAs semiconductor with a high aluminium mole fraction (e.g. x>0.8) exhibits a reasonably high bandgap energy (e.g. for AlₓGa₁₋ₓAs 0.8<x<1.0, 2.6<E_{Γ}<3.0 eV respectively), but not large enough to avoid absorption of high energy photons in the solar spectrum. Note that around one quarter of photons in the solar spectrum have energy Eₚₕₒₜₒₙ>2.5 eV.

To gain some further insight into the significance of this absorption, FIG. 4 shows the absorptance as function of Eₚₕₒₜₒₙ for 30 nm-thick layers of Al_{0.8}Ga_{0.2}As and AlAs (single pass absorptance A=(1−exp(−α.l)), as calculated from their bulk absorption coefficients. Absorptance is the fraction or proportion of incident light absorbed within a given thickness of semiconductor, l. It also shows the solar photon flux as a function of photon energy. Although the solar photon flux is reducing with photon energy, a significant proportion will be absorbed by an Al_{0.8}Ga_{0.2}As window layer. Using a higher Al mole fraction would reduce this by shifting the onset of absorption to higher energies, improving the overall device performance.

Unfortunately, semiconductors with a high aluminium mole fraction (x>0.7) also have a propensity to undergo atmospheric oxidation/hydrolysis, given the affinity of aluminium for oxygen [see References 6, 7, 8]. For example, it is generally accepted that an AlₓGa₁₋ₓAs aluminium mole fraction greater than 0.80<x<0.85 (corresponding to 2.6<E_{Γ}<2.7 eV) should not be used as a window layer in practice, due to the adverse effects of oxidation/hydrolysis [see References 6, 9]. However, being limited to using a window material with lower bandgap energy obviously compromises the transmittance of the window layer and device performance.

Even with x=0.80-0.85, substantial oxidation/hydrolysis of AlₓGa₁₋ₓAs can still occur, and steps must be taken to minimise its impact on the device performance [see References 10, 11]. As a consequence of the susceptibility of the window layer to oxidation/hydrolysis, a known compromise is to substitute AlₓGa₁₋ₓAs with a layer of AlₓIn₁₋ₓP with x about 0.5 [see Reference 12]. It has been claimed that this composition is more resistant to oxidation, but the transmittance of the window layer is still limited by its bandgap energy E_{Γ}=2.5.

As shown in FIG. 2, a typical photovoltaic device is grown with a highly doped semiconductor cap layer (e.g. p⁺-GaAs) covering the entire surface. The purpose of the cap layer is to reduce the specific contact resistance between the metal contact grid and the semiconductor device. It is only typically needed in the ‘shadowed’ areas underneath the metal contact grid, where it is in intimate contact with the metal. In fact, as it is highly optically absorbing to useful photons, the thick cap layer should preferably be removed elsewhere from the window layer prior to the deposition of the ARC (anti-reflection coating).

To carry out this etching, it is desirable to use a repeatable process that automatically stops etching as soon as the cap layer is entirely removed from the areas between all of the metal grid lines. A selective etching process is used for this purpose, typically using the window layer itself as the etch-stop layer and the metal grid lines as a self-aligned mask.

The etch selectivity S of an etching system is defined as the ratio of the etch rate of the first layer (i.e. the cap layer) over that of the second layer (i.e. the window layer). In order to etch through the first layer at a practical rate and effectively stop at the second layer, S is preferably significantly greater than unity. The selectivity is provided by choosing an appropriate etching process (e.g. wet etching in a C₆H₈O₇:H₂O₂ solution) in which the etch rate is dependent on the material composition (e.g. the aluminium mole fraction in AlₓGa₁₋ₓAs).

Using a selective etch process, one can:
over-etch (etch for longer than the nominal etching time), to ensure complete removal of the cap layer,
obtain a precise, uniform etch depth,
obtain a smooth final surface, even if GaAs etching rate was spatially uneven, which provides an excellent surface on which to deposit the ARC.

For example, citric acid: hydrogen peroxide (C₆H₈O₇:H₂O:H₂O₂) solution can be used to etch GaAs selectively over AlₓGa₁₋ₓAs with a high degree of selectivity for a wide range of aluminium fraction. Reference 13 demonstrated that an etch selectivity of S>100 can be achieved for etching GaAs over Al_{0.3}Ga_{0.7}As, and S>1400 for GaAs over AlAs.

There are some disadvantages to this approach, however. The window layer is exposed to the selective etch chemistry, and is therefore modified to some extent (e.g. partially etched, oxidised, roughened) during this process. Strictly speaking, unless S=infinity, a selective etch does not really ‘stop’ on the etch-stop layer (second layer); the etch rate merely slows. Further, although the dissolution rate of the reaction products may be low, the reaction-front may continue to penetrate into the etch-stop layer ahead of the etch-front. A certain depth of the etch-stop layer may be modified (e.g. oxidized) by the selective etch. For instance, the reaction of thick (100 nm, 750 nm) AlAs layers with C₆H₈O₇:H₂O₂ solution has been shown to convert a significant thickness (hundreds of nanometers) of AlAs into oxides [Reference 14]. Not unlike atmospheric hydrolysis of AlAs, the resulting layer is thicker (about twice as thick as the original un-oxidised layer) and is cracked at regular intervals due to stress. These micro-cracks can compromise the integrity of the etch-stop layer, allowing the etchant to punch through to the layer beneath. In contrast, it has been reported that very thin (e.g. about 1.5-2 nm) AlAs layers can be used successfully as etch-stop layers, presumably since the cumulative strain of the thin oxide layer is low enough to be accommodated [References 15, 16, 17].

Regardless of which process is used to etch the cap layer, the window layer will no longer be protected from oxidation/hydrolysis once it is uncovered.

Semiconductor materials that are used for the manufacture of photovoltaic cells (e.g. Si, GaAs, InP) possess high refractive indices; thus, more than 35% of incident sunlight is lost by reflection in circumstances where an anti-reflection coating (ARC) is not used. An accurate ARC is a key structural element for producing photovoltaic devices with high external quantum efficiency. By coating the front surface of the cell with a layer, or stack of layers, of appropriate thickness and refractive index, it is possible to achieve efficient optical coupling between the outer medium (e.g. vacuum, air, silicone rubber, etc.) and the photovoltaic layers of the device (e.g. emitter layer). As a result, reflection losses are minimized and thus the number of incident photons actually reaching the device active areas is maximized.

It has been established previously that a particularly suitable arrangement for ARC dielectric over-layers for GaAs heteroface solar cells is a MgF₂/ZnS double-layer coating with thicknesses of the respective layer depending on the window layer thickness and composition [Reference 9]. Every layer, including the window layer etc., that lies between the outer medium and the photovoltaic layers of the device should be taken into consideration in the overall ARC design and optimization. In order to design and implement an accurate ARC, the precise thickness and refractive index of all of these layers are preferably known and taken into account prior to the deposition of the ARC dielectric layer(s), and it is preferred that these parameters remain stable thereafter. Differences in the window layer structure, thickness and/or refractive index profile will lead to changes in ARC performance.

Exposed semiconductor surfaces can undergo reactions with oxygen-containing species (e.g. O₂, H₂O) that convert semiconductor material into oxides and/or hydroxides. As oxides/hydroxides, they can have very different electrical, optical and physical properties (e.g. thickness, refractive index, density, micro-structure) from the original material.

As mentioned above, it is well-known that AlₓGa₁₋ₓAs is highly susceptible to oxidation/hydrolysis, especially for compositions with high aluminium fractions (x>0.7). On exposure to moisture, AlₓGa₁₋ₓAs can undergo hydrolysis at ambient temperatures, forming a rather unstable native oxide layer. As the phase of oxide/hydroxide formed under these conditions occupies a larger volume than the original AlₓGa₁₋ₓAs layer, the mechanical stress induced can also result in micro-cracks [Reference 8]. The rate, thickness and quality of the native oxide that forms will depend on a number of factors, e.g. the aluminium mole fraction and thickness of the window layer, exposure to air/moisture, exposure time, temperature. Thermal treatments during any step of device fabrication or exposures to air prior to ARC deposition might cause the formation of an uncontrolled layer of AlₓGa₁₋ₓAs-oxide, which may be complicated to remove [Reference 10]. Assuming that the ARC is deposited within a short time after exposure to air, the impact of this thin oxide layer can be reduced, but it is difficult to ensure that the oxide properties will be identical from run-to-run.

It has been reported that, if left unprotected for as little as 24-48 hours, the oxidation/hydrolysis can consume the majority of a 40 nm Al_{0.91}Ga_{0.49}As window layer [References 9,18]. Using commercial thin-film coating design software we calculate the transmission of light (travelling at normal incidence to the layers) from air to GaAs media, through an anti-reflection coating (108 nm MgF₂/62 nm ZnS) and a Al_{0.85}Ga_{0.15}As window layer, with and without effects of oxidation/hydrolysis. FIG. 5a shows a plot of the transmission of light, T(λ), calculated for normal incidence when travelling from air to GaAs media, through an anti-reflection coating (108 nm MgF₂/62 nm ZnS) and Al_{0.85}Ga_{0.15}As window layer for two cases; namely, the layer structure shown in FIG. 5b where the window is a pure 40 nm thick Al_{0.85}Ga_{0.15}As layer (solid curve in FIG. 5a), and the layer structure shown in FIG. 5c where the window layer is partially oxidized (dashed curve in FIG. 5a), comprising 42 nm native oxide on 12 nm Al_{0.85}Ga_{0.15}As. The transmission was calculated using the commercial thin-film coating design software ‘The Concise MacLeod’ [Reference 19] and using complex refractive index values taken from Reference 5, in which n=1.78 was assumed for the native oxide). FIG. 5a therefore shows the dramatic reduction in transmission of light that would occur in this case where 28 nm of the Al_{0.85}Ga_{0.15} is converted to 42 nm of native oxide.

It may be possible to manufacture a solar cell without ever exposing the window layer to air. For instance, in the cell structure given in FIG. 2, this may be achieved by using a dry etching process to remove the cap layer, followed directly by ARC deposition without any intermediate exposure to air. However, this approach limits the choice of cap removal etch process. Further, this approach still does not totally eliminate the possibility of oxidation of the window layer, since the materials used in the ARC are usually porous and/or hygroscopic, and can suffer from pin-hole formation [References 10, 12]. As such, they cannot serve as good diffusion barriers to the ingress of oxidizing species. Furthermore, it is not always practical, or desirable, to deposit the ARC immediately following the cap removal etch.

Assuming that the ARC is deposited within a short time after exposure to air, the impact of a thin oxide layer can be reduced, but it is difficult to ensure that the oxide properties will be identical from run-to-run. This causes problems for large-scale production processes in which it is desirable for the efficiency of the devices to be high and uniform.

The present inventors have devised devices and methods of manufacturing devices that address one or more of the problems identified above, in order to avoid, reduce or ameliorate one or more of these problems.

In a general aspect, the present invention provides a window protection layer formed over the window layer, and/or an etch stop layer formed over the window layer, providing protection from degradation of the window layer during manufacture and/or operation of the device.

In a first preferred aspect, the present invention provides a semiconductor-based optoelectronic device having an n-type layer and a p-type layer, together forming a p-n junction, the device further including:
at least one contact region;
at least one light-receiving or light-transmitting region;
a window layer formed over the n-type layer or the p-type layer, at least at said light-receiving or light-transmitting region, the window layer providing, in operation, at least partial transmission of incident or generated light through to or from the n-type layer or p-type layer, and promoting reduced carrier recombination at the surface of the n-type or p-type layer, and/or at least partial reflection of minority carriers in the n-type or p-type layer towards the p-n junction,
   wherein the device has a window protection layer formed over the window layer, the window protection layer providing protection from degradation of the window layer during manufacture and/or operation of the device.

Preferred and optional features for this first preferred aspect will now be set out. These are applicably either singly or in any combination with the first aspect and/or with any other aspect of the invention, unless the context demands otherwise.

The present invention may be applied not only to devices with single p-n junctions, but also to devices with more than one p-n junction. For example, the device may have multiple p-n junctions, connected by tunnelling junctions. Examples of such devices are multi-junction solar cells.

Preferably, the window protection layer provides protection against degradation by oxidation and/or hydrolysis of the window layer.

The device may further include an anti-reflection coating formed at least at said light receiving region, the anti-reflection coating being formed over the window protection layer.

Preferably, the thickness of the window layer is at least 5 nm. In some circumstances, this thickness may be at least 10 nm. Preferably, the thickness of the window layer is at most 1.5 μm. In some circumstances, this thickness may be at most 0.5 μm.

Preferably, the thickness of the window protection layer is at least 1 ML (monolayer). In some circumstances, this thickness may be at least 1 nm. Preferably, the thickness of the window protection layer is at most 0.5 μm. In some circumstances, this thickness may be at most 10 nm.

Preferably, the contact region includes a layer of semiconducting contact material formed over the window protection layer. This is preferred in order to provide good electrical contact between the device and the outside world. The thickness of this layer of semiconductor contact material is preferably at least 5 nm, although this layer may have a thickness in the range 200-600 nm. An etch-stop layer may be sandwiched between the layer of semiconducting contact material and window protection layer. This is, in effect, an artifact of the processing history of the device. The etch-stop layer is thin, and so does not have a serious deleterious effect on the electrical connection between the device and the outside world.

The etch-stop layer may be formed of a material having an etching rate of at least 10 times slower than an etching rate of the semiconducting contact material under the same predetermined etching conditions. This is the etch selectivity S of the system and is preferably at least 20, at least 30, at least 40, at least 50 or higher. A preferred lower limit for S is 100. S may be up to 1400, or higher.

The etch stop layer may comprise III-V semiconducting material, such as a material falling within the general formula AlₓGa₁₋ₓAs. Most preferably, the etch stop layer is AlAs. The etch stop layer (e.g. formed from AlAs) may have a thickness of up to 10 nm. Particularly for AlAs, etch stop layers of greater thickness than this (e.g. 80-100 nm) can have problems due to cracking, caused by oxidation. An AlAs etch stop layer of thickness about 2 nm has been found to work well. A relatively thin etch stop layer can minimise the increase in series resistance caused by the introduction of the etch stop layer. If the etch stop layer has a different composition in the composition range AlₓGa₁₋ₓAs (e.g. Al_{0.8}Ga_{0.2}As or Al_{0.7}Ga_{0.3}As) then a thicker etch stop layer may be used, since such compositions may have a smaller cracking problem due to oxidation. In those cases, etch stop layers of thickness up to 1 μm may be used, e.g. where the composition of the etch stop layer is AlₓGa₁₋ₓAs with x>0.5.

Preferably, the device includes a substrate and the n-type and p-type layers are epitaxial layers, the device optionally including intermediate layers between the substrate and the n-type or p-type layers. Preferably, the n-type layer and p-type layer are each based on group III-V semiconducting material. Preferably, the group III-V semiconducting material is Ga—As based material. Such materials have been shown to provide high efficiency optoelectronic devices, especially high efficiency solar cell devices.

Preferably, In is substantially absent from the window layer. This allows the window layer to have a high bandgap energy, thereby making it a more efficient window layer, since it absorbs fewer useful photons, for example, in a typical solar spectrum.

Preferably, the window layer comprises AlₓGa₁₋ₓAs in which x is greater than 0 and at most 1. Preferably, x is at least 0.7, or more preferably at least 0.75, 0.80, 0.85, 0.90, 0.95, 0.98 or at least 1.00, in order to ensure that the window layer has a high bandgap energy. A particularly preferred composition for the window layer is Al_{0.9}Ga_{0.1}As. The bandgap energy of the window layer is preferably 2.5 eV or above, or more preferably 2.7 eV or above. It is preferred that the bandgap energy of the window layer is about 4 eV or higher. This allows substantially the complete solar spectrum to be absorbed by the underlying layers. However, in some circumstances the lower limit for the bandgap energy of the window layer is lower than this, for reasons of lattice matching (although pseudo- or meta-morphic layers might be used), compatibility of the materials used in the different layers, electro/optical quality, crystallinity and other factors that will be understood by the skilled person.

Preferably, a band gap energy of the window protection layer is at most 2.6 eV (for example, Al_{0.8}Ga_{0.2}As has a band gap energy of about 2.58 eV, and GaAs has a band gap energy of about 1.42 eV). The window protection layer therefore would be expected to reduce the efficiency of the device, especially where the device is a solar cell. However, the present inventors have shown that the window protection layer can unexpectedly in fact provide an overall benefit to the device.

Preferably, the window protection layer comprises Ga—As based material, such as GaAs.

The optoelectronic device is preferably a photovoltaic device (e.g. photodiode), such as a solar cell. However, it is possible for the device to be a phototransistor, light-emitting diode, or laser diode.

In a second preferred aspect, the present invention provides a semiconductor-based optoelectronic device having an n-type layer and a p-type layer, together forming a p-n junction, the device further including:
at least one contact region;
at least one light-receiving or light-transmitting region;
a window layer formed over the n-type layer or the p-type layer, at least at said light-receiving or light-transmitting region, the window layer providing, in operation, at least partial transmission of incident or generated light through to or from the n-type layer or p-type layer, and promoting reduced carrier recombination at the surface of the n-type or p-type layer, and/or at least partial reflection of minority carriers in the n-type or p-type layer towards the p-n junction,
   wherein the contact region includes a layer of semiconducting contact material, with an etch-stop layer sandwiched between the semiconducting contact material and the window layer.

As will be appreciated, this second aspect differs from the first aspect in that a window protection layer is not necessarily present in the final product (although such a layer may preferably be present). The etch stop layer is located in the contact region in the final product. During manufacture (at least), the etch stop layer is located above the window layer, but it is not essential for the etch stop layer to be present above the window layer in the final product (although this etch stop layer may be present in preferred embodiments). The advantage of using an etch stop layer in this way is that it may allow the contact material to be etched to an exact depth, which is advantageous in terms of leaving a known surface on which to deposit further layers, such as an anti-reflection coating(s).

Preferred and/or optional features of the first aspect apply also to the second aspect.

In a third preferred aspect, the present invention provides a method of manufacturing a semiconductor-based optoelectronic device, the device having an n-type layer and a p-type layer, together forming a p-n junction, the method including the steps:
forming a window layer over the n-type layer or the p-type layer;
forming a window protection layer over the window layer;
optionally, forming an etch-stop layer over the window protection layer
forming a layer of semiconducting contact material over the window protection layer or over the etch-stop layer, if present;
etching the layer of semiconducting contact material under a semiconducting contact material etching condition in at least one region corresponding to a light-receiving or light-transmitting region of the final device, to leave at least one light-receiving or light-transmitting region and at least one contact region, the etching stopping at the window protection layer or at the etch-stop layer, if present; and
optionally, removing the etch-stop layer, if present, at least from the light-receiving or light-transmitting region.

Preferred and/or optional features of the first or second aspect apply also to the third aspect.

The window protection layer and the etch stop layer may in fact be the same layer, i.e. a single layer may function as both the window protection layer and the etch stop layer.

The window protection layer or the etch-stop layer may have an etching rate under said semiconducting contact material etching condition of at least 10 times slower than the semiconductor contact material. This is the etch selectivity S of the system and is preferably at least 20, at least 30, at least 40, at least 50 or higher. A preferred lower limit for S is 100. S may be up to 1400, or higher.

Preferably the semiconducting contact material etching condition includes the use of an etchant comprising an oxidising agent for oxidising the semiconducting contact material and an agent for dissolving the oxidised semiconducting contact material. The etchant preferably comprises citric acid: hydrogen peroxide (C₆H₈O₇:H₂O₂) solution.

Other possible selective etchant systems include:
C₆H₈O₇ (citric acid):H₂O₂-based (cooling this selective wet etching solution can provide an anisotropic etching profile)
C₆H₈O₇ (citric acid):K₃C₆H_{S}O₇ (potassium citrate):H₂O₂-based
C₆H₈O₇ (citric acid):NH₄OH:H₂O₂-based
C₄H₈O₄ (succinic acid):H₂O₂-based, pH-adjusted (e.g. using NH₄OH)
C₄H₆O₆ (tartaric acid)-based
C₂H₂O₄ (oxalic acid)-based
NH₄OH:H₂O₂-based, pH-adjusted
HF-, HCl-, H₂SO₄-, H₃PO₄-, HNO₃-, HI-, H₃PO₂-, or NH₄OH-based solutions, etc.
   Selective etching can also be performed using a dry etch chemistry (reactive ion etching); for example, a dry etch chemistry containing chlorine and fluorine e.g. CCl₂F₂-plasma, or SiCl₄:CF₃-plasma, or a dry chemistry containing methane and hydrogen, e.g. CH₄:H₂ plasma.

Preferably, the etch-stop layer is removed under an etch-stop layer etching condition, different from the semiconducting contact material etching condition. This step, if present, is important because the removal of the etch-stop layer determines the precise final depth, and thus the surface on which subsequent layers, such as anti-reflective coatings, will be deposited. Thus, the S for the second step should also be high, for example within any of the ranges set out above for S for the etching of the semiconductor contact material. Preferably, the ratio of the thickness of the etch-stop to the thickness of the window protection layer is low, e.g. close to or less than 1. Suitable selective etchant solutions include wet etch solutions containing HCl, or HF.

The method may further include subsequently forming an anti-reflective coating over at least the light-receiving or light-transmitting region.

In a fourth preferred aspect, the present invention provides a method of manufacturing a semiconductor-based photovoltaic device, the device having an n-type layer and a p-type layer, together forming a p-n junction, the method including the steps:
forming a window layer over the n-type layer or the p-type layer;
optionally, forming a window protection layer over the window layer;
forming an etch-stop layer over the window layer, or over the window protection layer, if present;
forming a layer of semiconducting contact material over the etch-stop layer;
etching the layer of semiconducting contact material under a semiconducting contact material etching condition in at least one region corresponding to a light-receiving or light-transmitting region of the final device, to leave at least one light-receiving or light-transmitting region and at least one contact region, the etching stopping at the etch-stop layer; and
optionally, removing the etch-stop layer at least from the light-receiving region.

In this method, the formation of the etch-stop layer is essential, whereas the formation of the window protection layer is optional (although preferred). This is in contrast to the third aspect.

Preferred and/or optional features of the first, second or third aspect apply also to the fourth aspect.

Further preferred and/or optional features are set out in the detailed description below.

### BRIEF DESCRIPTION OF THE DRAWINGS

FIG. 1 shows solar spectral irradiance (AM1.5D Direct+circumsolar, ASTM G173-03 reference spectra derived from SMARTS v. 2.9.2). The spectral region which can be absorbed by GaAs (i.e. Eₚₕₒₜₒₙ>E_{g}) is shaded.

FIG. 2a shows a schematic cross sectional view of a typical single-junction heteroface solar cell, and FIG. 2b shows the energy band diagram (under thermal equilibrium), calculated using a 1-D Poisson Solver for the structure of FIG. 2a.

FIG. 3 is a graph showing the solar photon flux (direct+circumsolar ASTM G173-03 reference spectra derived from SMARTS v. 2.9.2) and the absorption coefficient of bulk AlₓGa₁₋ₓAs with aluminium mole fraction x=0, 0.19, 0.80, 1.00 [Reference 5].

FIG. 4 is a graph showing the solar photon flux (direct+circumsolar ASTM G173-03 reference spectra derived from SMARTS v. 2.9.2) and the absorptance for 30 nm Al_{0.8}Ga_{0.2}As and 30 nm AlAs (calculated from bulk absorption coefficients).

FIG. 5a is a plot of the transmission of light, T(λ), calculated for normal incidence when travelling from air to GaAs media, through an anti-reflection coating (108 nm MgF₂/62 nm ZnS) and Al_{0.85}Ga_{0.15}As window layer for two cases; namely, the layer structure given in FIG. 5(i) where the window is a pure 40-nm-thick Al_{0.85}Ga_{0.15}As layer (solid curve in FIG. 5a), and the layer structure given in FIG. 5(ii) the window layer is partially oxidized (dashed curve in FIG. 5a), comprising 42 nm native oxide on 12 nm Al_{0.85}Ga_{0.15}As. The transmission was calculated using the commercial thin-film coating design software ‘The Concise MacLeod’ [Reference 19] and using complex refractive index values taken from Reference 5 (n=1.78 was assumed for the native oxide).

FIG. 6 illustrates schematically three design options applied to a heteroface GaAs solar cell.

FIG. 7 is a graph showing the solar photon flux (direct+circumsolar ASTM G173-03 reference spectra derived from SMARTS v. 2.9.2) and the absorptance calculated (based on bulk absorption coefficients, ignoring any quantum confinement effects) for 30 nm Al_{0.8}Ga_{0.2}As, 30 nm AlAs and 1 nm GaAs (ignoring quantum confinement effects).

FIG. 8 shows plots of the transmission of light, T(λ), calculated for normal incidence when travelling from air to GaAs media, through an anti-reflection coating, a GaAs window protection layer, and an Al_{0.85}Ga_{0.15}As window layer. Plots are given for air media/95 nm MgF₂/53 nm ZnS/1 nm GaAs/Al_{0.85}Ga_{0.15}As/GaAs media, air media/98 nm MgF₂/53 nm ZnS/2 nm GaAs/Al_{0.85}Ga_{0.15}As/GaAs media. For reference, also shown are plots from air to GaAs media, through an anti-reflection coating (91.9 nm MgF₂/53.3 ZnS) covering an as-grown (30 nm Al_{0.85}Ga_{0.15}As) and a part-oxidised (22 nm AlOₓ/10 nm Al_{0.85}Ga_{0.15}As) window layer. n=1.78 was assumed for the AlOₓ). The plots were calculated as for FIG. 5.

FIG. 9 shows a plot of etch depth against the time of selective etching of the contact semiconductor layer (p-type GaAs) over an etch stop layer.

FIG. 10 shows reflection spectra for a device with an AlGaAs window layer and no protection layer, the spectra measured over a period of 20 days. Also shown is the day 20 spectrum for a corresponding device with an anti-reflection coating.

FIG. 11 shows the results from an analysis of the reflection spectra measured over an 8-day period for an unprotected AlGaAs window layer. The lines show fitting using a multi-layer model.

FIGS. 12 and 13 show spectroscopic ellipsometry measurements over an 8-day period for an unprotected AlGaAs window layer. The lines show fitting using a multi-layer model.

FIGS. 14 and 15 show the results of a multi-layer model fit of the evolution of degradation of an unprotected AlGaAs window layer.

FIG. 16 shows the variation of refractive index (n) and extinction coefficient (k) at a wavelength of 400 nm for an unprotected AlGaAs window layer.

FIG. 17 shows the results of a multi-layer model fit on the stability of the layer thickness for a protected AlGaAs window layer.

FIG. 18 shows reflection spectra for a device with a protected AlGaAs window layer, the spectra measured over a period of 20 days. Also shown is the day 20 spectrum for a corresponding device with an anti-reflection coating.

FIG. 19 shows an isolated five micron metal line after etching a device according to an embodiment of the invention (SEM micrograph).

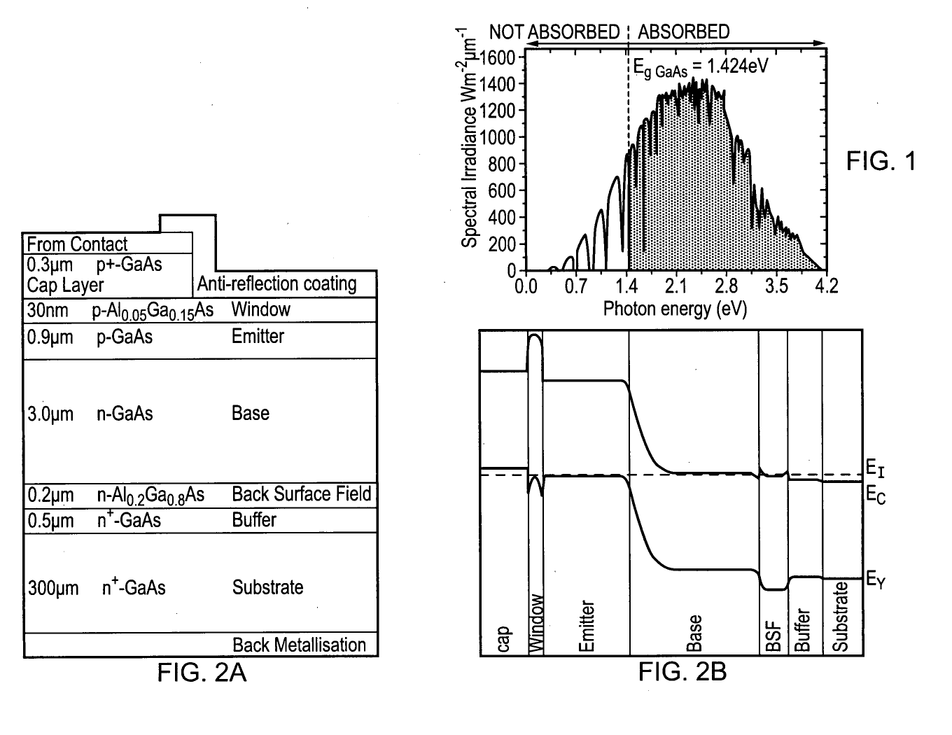

### DETAILED DESCRIPTION OF THE PREFERRED EMBODIMENTS

As explained above in relation to GaAs-based devices, in terms of the window performance, it is desirable to use a window layer having high aluminium fraction, but this is not generally advisable for practical reasons concerning oxidation/hydrolysis. The present inventors have devised devices and methods of fabrication in which it is possible to suppress exposure of the window layer to oxidizing species. In some preferred embodiments, this is done by ensuring that a protection layer (e.g. GaAs, (AlₓGa₁₋ₓ)_{0.51}In_{0.49}P, AlₓGa₁₋ₓAs) is maintained to cover the window layer during and after the removal of the contact layer (also referred to herein as “cap layer”).

In one embodiment, the protection layer itself can be employed as the etch-stop layer in the selective etching process of the cap layer. Alternatively, in another embodiment, a dedicated etch-stop layer is introduced (between the protection layer and cap layer (contact layer)). This etch-stop layer assists in the selective etching process of the cap layer. After the etch-stop layer has served its purpose, it may be removed using another selective etching process, before further device processing (e.g. the subsequent deposition of an ARC). Alternatively, it may be left in place, with/without further modification (e.g. densification/dehydration by thermal annealing), before further device processing (e.g. the subsequent deposition of an ARC).

Three design options as set out in Tables 1, 2 and 3 below.

TABLE 1
Design option I - combined etch-stop and protection
layer.

| As-grown epitaxial | | |
|---|---|---|
| structure | Shadowed regions | Unshadowed regions |
| | Electrically- | |
| | conducting layer(s) | |
| Cap layer(s) | Cap layer(s) | ARC/TCO |
| Etch-stop/ | Etch-stop/ | Etch-stop/ |
| protection layers | protection layers | protection layers |
| Window layer(s) | Window layer(s) | Window layer(s) |
| Device sublayer(s) | Device sublayer(s) | Device sublayer(s) |

TABLE 2
Design option II - separate etch-stop and protection layers.
Etch-stop removed before ARC deposition.

| As-grown epitaxial | | |
|---|---|---|
| structure | Shadowed regions | Unshadowed regions |
| | Electrically- | |
| | conducting layer(s) | |
| Cap layer(s) | Cap layer(s) | |
| Etch-stop layer(s) | Etch-stop layer(s) | ARC/TCO |
| Protection layer(s) | Protection layer(s) | Protection layer(s) |
| Window layer(s) | Window layer(s) | Window layer(s) |
| Device sublayer(s) | Device sublayer(s) | Device sublayer(s) |

TABLE 3
Design option III - separate etch-stop and protection layers.
Etch-stop not removed before ARC deposition.

| As-grown epitaxial | | |
|---|---|---|
| structure | Shadowed regions | Unshadowed regions |
| | Electrically- | |
| | conducting layer(s) | |
| Cap layer(s) | Cap layer(s) | ARC/TCO |
| Etch-stop layer(s) | Etch-stop layer(s) | Etch-stop layer(s) |
| Protection layer(s) | Protection layer(s) | Protection layer(s) |
| Window layer(s) | Window layer(s) | Window layer(s) |
| Device sublayer(s) | Device sublayer(s) | Device sublayer(s) |

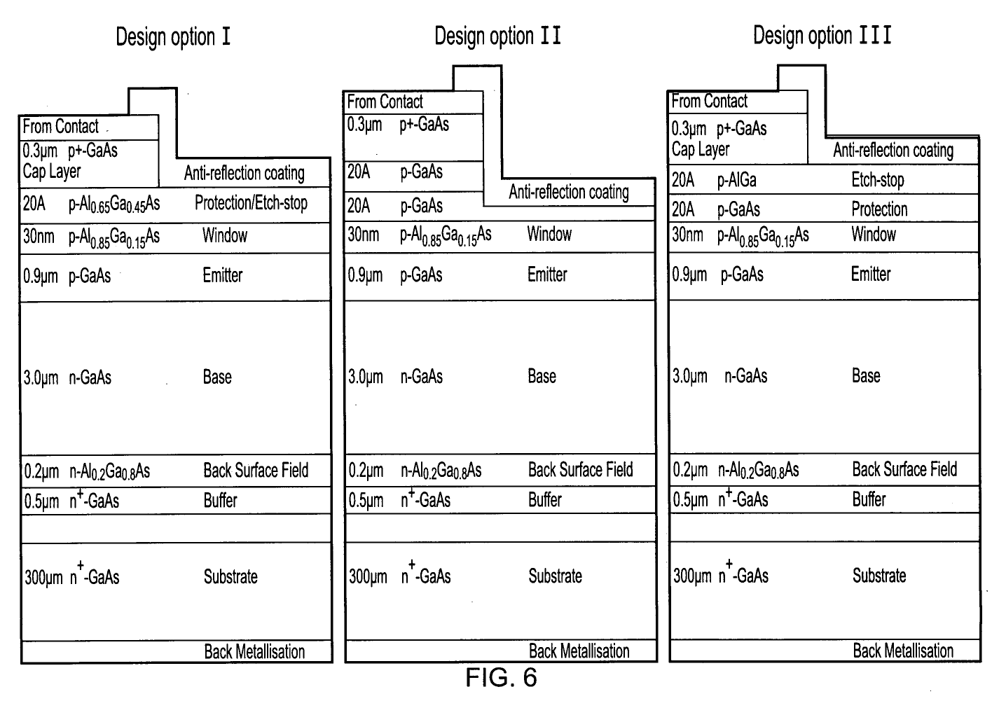

These design options are further illustrated in FIG. 6. The structure and function of the window protection layer and of the etch-stop layer are described below.

### Window Protection Layer

To suppress oxidation/hydrolysis of the window layer, a window protection layer is introduced. The window protection layer covers the window layer. The window protection layer is composed of a semiconductor material that has a substantially lower propensity to oxidise/hydrolyse than the window layer. For example, candidate materials include AlₓGa₁₋ₓAs with 0<x<0.8, and (AlₓGa₁₋ₓ)_{0.51}In_{0.49}P with 0<x<1.0. In general, the lower the aluminium content of a semiconductor, the more resistant it is against oxidation/hydrolysis in a GaAs-based system.

Note that an AlₓGa₁₋ₓAs with x=0 (i.e. GaAs) surface is also susceptible to atmospheric oxidation. However, in this case, the oxide forms a dense, unbroken layer with a thickness of about 3 nm after 8 days [Reference 20]. The diffusion-limited growth rate is highly parabolic with d(nm)=0.5969+0.5929 log [t(min)]. Soaking GaAs in H₂O₂ forms a stable native oxide that is about 1.4-1.7 nm thick, and the logarithmic growth rate is considered to be slow enough to be effectively a self-limiting (diffusion-limited) process [Reference 21].

Since the window protection layer generally has a relatively low aluminium fraction, it also has a lower bandgap energy than the window layer. Hence, in order to avoid substantial absorption of useful photons, the window protection layer should not be thicker than is necessary to prevent or significantly reduce oxidation of the window layer. The minimum window protection layer thickness required depends on the layer composition, device design and device processing, but it is in the range of approximately 1-60 ML (ML is monolayer) [Reference 22]. The maximum thickness that is advisable depends on the bandgap energy of the protection layer and the energy range of useful photons.

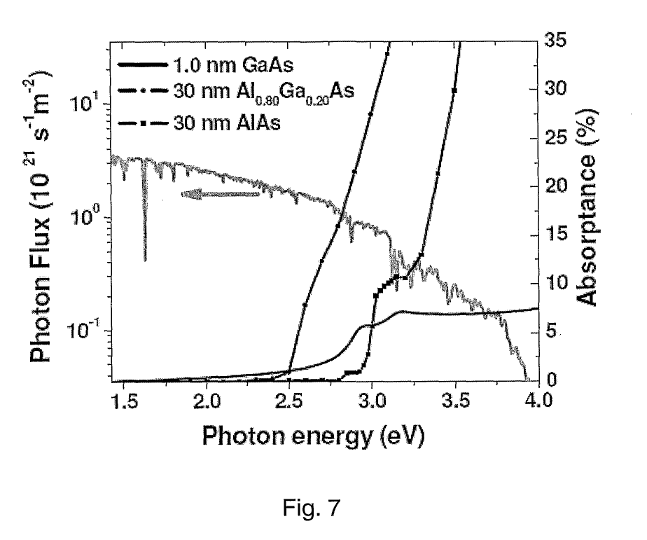

FIG. 7 illustrates the absorptance of a 1 nm thick window protection layer of GaAs (based on bulk absorption coefficients, ignoring any quantum confinement effects), showing that the layer thickness should be kept to a minimum. Using an AlₓGa₁₋ₓAs or (AlₓGa₁₋ₓ)_{0.51}In_{0.49}P window protection layer, the absorptance decreases with increasing x.

It is expected that, when the thickness of the window protection layer is very small, the absorption coefficient may be different than that for bulk layers, due to quantum confinement effects. High doping levels may also modify the absorption coefficients, due to bandgap narrowing and the band-filling effect known as the Burstein-Moss shift [Reference 23].

### Combined Etch-Stop and Window Protection Layer

In principle, as long as the composition of the window protection layer is not identical to that of the cap layer, there is potential for the protection layer to also function as an etch-stop layer during the selective etching process that removes the cap layer. For example, this is possible in the case of the epitaxial layer structure tabulated in Table 4. The GaAs cap layer can be etched selectively over Al_{0.3}Ga_{0.7}As [Reference 24] such that the Al_{0.3}Ga_{0.7}As layer functions as an effective etch-stop layer. For the selective etching of GaAs over Al_{0.3}Ga_{0.7}As, Reference 25 reported S=116 using a C₆H₈O₇:H₂O₂-based etch, and for selective etching of GaAs over Al_{0.2}Ga_{0.8}As, Reference 26 reported selectivity as high as S=256 using a C₆H₈O₇:H₂O:H₂O₂-based etch. In addition, the Al_{0.3}Ga_{0.7}As layer serves to protect the window layer from the selective etch solution and any exposure to water/air with a precisely known thickness of Al_{0.3}Ga_{0.7}As material that is resistant to oxidation/hydrolysis.

TABLE 4
Example of an epitaxial structure to implement the design
with a combined etch-stop and protection layer.

| | |
|---|---|
| 300 nm GaAs | cap layer |
| 3.5 nm Al_{0.3}Ga_{0.7}As | etch-stop/protection layer |
| 30 nm Al_{0.9}Ga_{0.1}As | window layer |
| | device sublayer(s) |

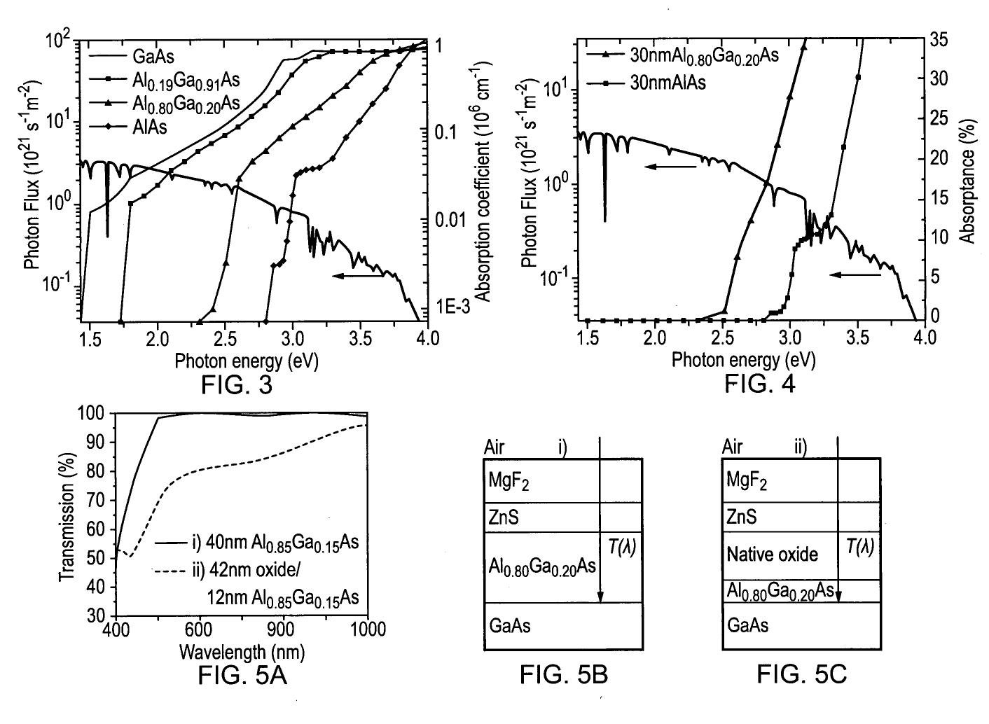

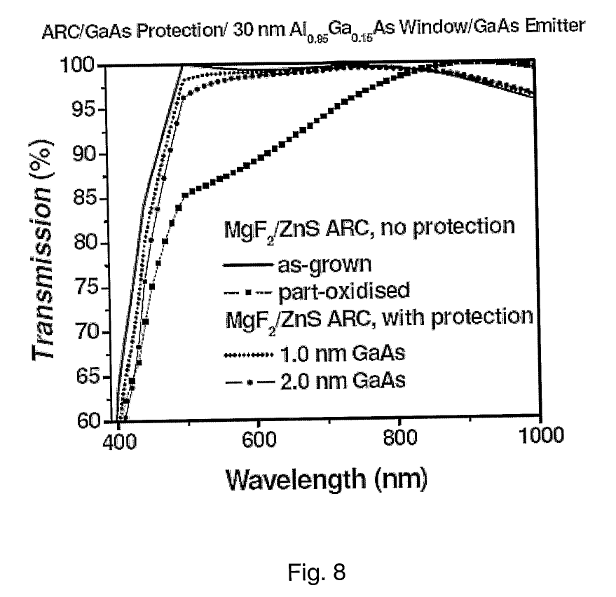

FIG. 8 shows plots of the transmission of light, T(λ), calculated for normal incidence when travelling from air to GaAs media, through an anti-reflection coating (108 nm MgF₂/62 nm ZnS), a GaAs window protection layer of 1.0 nm or 2.0 nm, and Al_{0.85}Ga_{0.15}As window layer. For reference, also shown are plots for as-grown and part-oxidised layers with the anti-reflection coating. The plots were calculated as for FIG. 5.

### Separate Etch-Stop and Window Protection Layers

In another embodiment (see Table 2 and FIG. 6), a second layer is introduced, between the window protection layer and the cap layer. This layer is dedicated to functioning as an etch-stop layer in the selective etching process of the cap layer. The etch-stop layer is composed of a semiconductor that provides etch selectivity during the process of removing these areas of the cap layer(s) by an appropriate wet/dry selective etching process.

The introduction of a dedicated etch-stop layer provides several advantages:
allows more freedom in choice of the protection layer and etch-stop layer composition and thickness, and in the choice of the selective etch process
suppresses exposure of the window layer to oxidising/hydrolysing species during the selective etching process, and thereafter
permits cleaning (e.g. deoxidation) of the semiconductor surface prior to ARC deposition without damaging the window layer

For example, this it is possible to take advantage of these features in the case of the epitaxial layer structure shown in Table 5. The GaAs cap layer can be etched with very high selectively over AlAs [References 13,15]. Then, if desired, the thin AlAs layer (and any native oxides) can be etched away with high selectively over Al_{0.3}Ga_{0.7}As [Reference 35] leaving a clean Al_{0.3}Ga_{0.7}As window protection layer in place, ready for the ARC layer deposition.

TABLE 5
Example of an epitaxial structure to implement a design with
separate etch-stop and window protection layers.

| | |
|---|---|
| 300 nm GaAs | cap layer |
| 2 nm AlAs | etch-stop layer |
| 3.5 nm Al_{0.3}Ga_{0.7}As | protection layer |
| 30 nm Al_{0.9}Ga_{0.1}As | window layer |
| | device sublayer(s) |

Alternatively, the etch-stop can be left in place after removing the cap layer, with/without further modification (e.g. densification/dehydration by thermal annealing), before further device processing (e.g. the subsequent deposition of an ARC).

If the etch-stop layer itself is not to be etched from the device during processing, the used etch-stop layer may be treated in some other way. For example, it may be thermally annealed prior to the ARC deposition in order to modify its composition and change any hydroxide phases to denser, more stable oxide phases, and/or to deplete elemental arsenic and arsenic-based compounds (e.g. As, As₂O₃). When densified, the native oxide layer can provide an additional barrier against oxidation/hydrolysis of the underlying layers.

Selective etching may be performed using a wet etch chemistry [Reference 27]. The selectivity depends on the materials wet etch solution used. For example, selective wet solutions include:
C₆H₈O₇ (citric acid):H₂O₂-based [References 24, 28, 29] (cooling this selective wet etching solution can provide an anisotropic etching profile [Reference 30])
C₆H₈O₇ (citric acid):K₃C₆H_{S}O₇ (potassium citrate):H₂O₂-based [Reference 31]
C₆H₈O₇ (citric acid):NH₄OH:H₂O₂-based [Reference 32]
C₄H₆O₄(succinic acid):H₂O₂-based, pH-adjusted (e.g. using NH₄OH) [Reference 29]
C₄H₆O₆ (tartaric acid)-based [Reference 33]
C₂H₂O₄(oxalic acid)-based [Reference 29]
NH₄OH:H₂O₂-based, pH-adjusted [Reference 29]
HF-, HCl-, H₂SO₄-, H₃PO₄-, HNO₃-, HI-, H₃PO₂-, or NH₄OH-based solutions, etc. [References 24, 34, 35]

Selective etching can also be performed using a dry etch chemistry (reactive ion etching). For example, a dry etch chemistry containing chlorine and fluorine e.g. CCl₂F₂-plasma, SiCl₄:CF₃-plasma or a dry chemistry containing methane and hydrogen, e.g. CH₄:H₂ plasma.

### Further Preferred Features

It is preferred that the window layer and cap layer are doped to be the same conductivity type as the device layer (e.g. emitter) beneath it. For instance, for a p-n heteroface solar cell configuration (with an n-GaAs substrate, n-GaAs base, and p-GaAs emitter) in which the window layer sits directly upon a p-type (about 2×10¹⁸ cm⁻³) emitter layer, the window layer and cap layer should both be p-type doped (about 5×10¹⁸ cm⁻³ and about 5×10¹⁹ cm⁻³, respectively). Similarly, the protection and etch-stop layers should be doped to be the same conductivity type (or nominally undoped).

The window protection, etch-stop and cap layers are preferably doped. A variety of different semiconductor materials may be used in the window, window protection, and cap layer, including one or more of: GaAs, AlAs, InAs, GaInAs, AlGaAs, AlInAs, AlGaInAs, GaP, AlP, InP, AlInP, AlGaInP, GaInP, AlGaAsP, GaInPAs, AlInPAs, AlGaInPAs, GaSb, InSb, AlSb, GaAsSb, AlAsSb, AlInSb, GaInSb, GaAlAsSb, AlGaInSb, AlN, GaN, InN, Ga₁₋ₙN, AlGaInN, GaInNAs, AlGaInNAs, ZnSSe.

The window, window protection, etch-stop and/or cap layers may be composed of lattice-mismatched (to substrate and/or layer beneath the window layer) semiconductor(s). Such an arrangement is set out, for example, in U.S. Pat. No. 7,119,271 [corresponding to Reference 36].

The light-emitting/light-absorbing layers of the device may contain arrangements of quantum-wells and/or quantum dots.

At least one of the layers in the device may be composed of digital alloys.

At least one of the layers may be composed of a series of semiconductor materials, or be graded (continuous, stepped or digitally), in composition.

The window layer may be graded (continuously, stepped or digitally) in composition such that the bandgap increases towards the illuminated side. This encourages any minority carriers that are generated in the window layer to migrate to the emitter. It can also help reduce drops in electrical potential across the window layer.

The window protection layer may be graded in composition such that the bandgap decreases towards the illuminated side, such as to minimize absorption in the protection layer while maintaining its stability against oxidation/hydrolysis.

A passivation layer (e.g. silicon nitride, SiNₓ, which forms a good diffusion layer against oxidizing species) may be deposited prior to the ARC formation (or form part of, or all of, the ARC layer).

The schemes proposed here do not preclude the use of epitaxial lift-off (ELO)/substrate transfer. Indeed, the layer sequence can be grown in reverse sequence, and a suitable epitaxial lift-off technique used to remove the substrate and expose the cap layer for processing as described. Additional etch-stop layers can be added above the cap layer (i.e. grown before the cap layer) to assist in ELO.

### Semiconductor Cap Layer

Low bandgap semiconductor materials (e.g. InAs, InₓGa₁₋ₓAs grown on metamorphic buffer layers) can be used to further reduce the specific contact resistance between the metal contact and the semiconductor layers.

Growth of a very highly doped cap layer(s) of semiconductor (for example, GaAs, InₓGa₁₋ₓAs 0<x<1) reduces the specific contact resistance between the metal contact and the semiconductor device layer. Typically, a doping density within the 1×10¹⁸ to 1×10²⁰ cm⁻³ range is used in the cap layer. p⁺⁺-GaAs (C) or p⁺⁺-InGaAs(C) may be used to provide low specific contact resistance.

Typically, the cap layer thickness is about 200-600 nm. Increasing thickness may increase the series resistance of the device. Decreasing the thickness may result in elements from the ohmic contact metallization (and defects associated with the ohmic contact formation) diffusing into the active regions of the device, with detrimental effects on performance.

Delta-doping may be in the semiconductor cap layer to decrease the specific contact resistance between the semiconductor cap layer and the metal contact.

### Ohmic Metallisation

Cr/Au, Ti/Pd/Au, Pd/Ti/Pd/Au, Ti/Pt/Au, Pd/Ti/Pt/Au, Zn-containing alloys (for example, AuZn), or Be-containing alloys (for example, AuBe) may be used for forming electrical contacts to a p-type semiconductor used as the semiconductor cap layer or to a p-type semiconductor used as the semiconductor substrate.

Cr/Au, Ti/Pd/Au, Pd/Ti/Pd/Au, Ti/Pt/Au, Pd/Ti/Pt/Au, Au/Ge/Au/Pd/Au, Pd/Ge/Au/Pd/Au, Au/Ge/Au/Ni/Au, Pd/Ge/Au/Ni/Au or Ge-containing alloys may be used for forming electrical contacts to n-type semiconductor, where n-type semiconductor is used as the semiconductor cap layer or to a n-type semiconductor used as the semiconductor substrate.

Pre-treatment of the semiconductor surface may be carried out using oxygen plasma (asking) prior to ohmic contact deposition. This step is typically used to remove resist/carbon residues.

Pre-treatment of semiconductor surface may be carried out using de-oxidising/passivating wet chemical solutions prior to ohmic contact deposition. For example, such solution may be based on HCl, H₂SO₄, NH₄OH, (NH₄)₂Sₓ.

Pre-treatment of the semiconductor surface may be carried out using dry plasma-based chemistries prior to ohmic contact deposition. For example, nitrogen-based or argon-based plasmas may be used.

### ARC

An anti-reflective coating may be designed and implemented using a single layer or multiple layers of dielectric material(s) of the appropriate optical thickness, the design of which is known to those skilled in the art. A preferred single layer system is a layer of SiNₓ of the appropriate refractive index and thickness. Other systems include a dual layer ARC of ZnS/MgF₂, TiO₂/M_{g}F₂ or Ta₂O₃/MgF₂. Anti-reflective coatings may include sub-layers of many different materials, some of which are as follows: Al₂O₃, ZrO₃, MgF₂, SiO₂, cryolite, LiF, ThF₄CeF₃, PbF₂, ZnS, ZnSe, Si, Ge, Te, PbTe, MgO, Y₂O₃, Sc₂O₃, SiO, HfO₂, ZrO₂, CeO₂, Nb₂O₃, Ta₂O₅, and TiO₂ [Reference 1].

ARC protection may be provided using a hydrophobic over-layer. Typically, the hydrophobic layer is composed of an organosilane/fluorinated hydrocarbon. The hydrophobic layer may be applied in a layer that is as little as several nm in thickness. The hydrophobic layer may be applied by dipping the anti-reflective layer into a liquid bath of the hydrophobic polymer, or through vapour deposition or by other suitable methods. Various hydrophobic materials may be utilized that are well known to those skilled in the art [Reference 2].

The semiconductor layer thicknesses and compositions are most preferably included in the optimisation of the ARC performance.

### Test Results

FIG. 8 shows calculated plots of the transmission performance of solar cell structures having MgF₂/ZnS antireflective coating formed on 1.0 nm or 2.0 nm GaAs window protection layer, formed in turn on a 30 nm Al_{0.85}Ga_{0.15}As window on a GaAs emitter, in comparison to a solar cell structure having no GaAs window protection layer. As shown, the transmission of useful photons through to the light-absorbing regions of the solar cell structure is considerably improved in comparison with the situation where the 30 nm Al_{0.85}Ga_{0.15}As window is part oxidised.

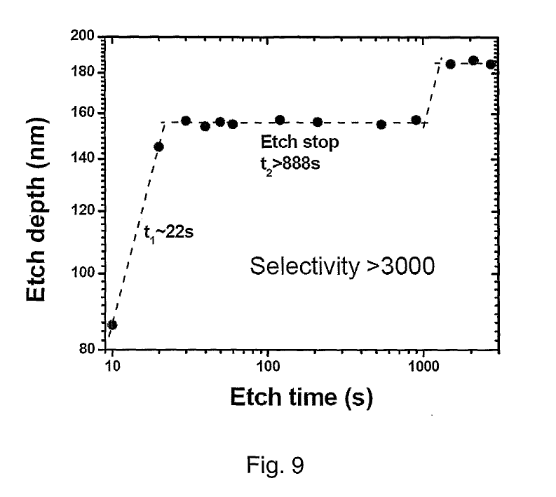

FIG. 9 shows the results of measurements carried out to determine the etch selectivity of an etching system designed to etch first the semiconductor cap layer at an appreciable rate, “stop” at an etch stop layer, and then the removal of the etch stop layer by a second stage of the etching system, this second stage then “stopping” once the etch-stop layer is removed, due to the window protection layer being formed directly beneath the etch stop layer. In FIG. 9, each sample was etched for a given time in citric acid solution/H₂O₂ etch 5:1, rinsed in deionised water, then etched for a 120 second fixed buffered HF solution 5:1 etch, all at room temperature. The citric acid solution was prepared by dissolving 500 g C₆H₈O₇.H₂O in 500 ml deionised water.

TABLE 6
the structure of the sample upon which the etch
tests in FIG. 9 were performed.

| Composition | Thickness | Doping | Dopant | Description |
|---|---|---|---|---|
| GaAs | 150 nm | 5E+19 | Be | p⁺-Contact |
| AlAs | 2 nm | 5E+18 | Be | Etch stop |
| GaAs | 5 nm | 5E+18 | Be | Window protection |
| Al_{0.85}Ga_{0.15}As | 30 nm | 5E+18 | Be | Window |
| GaAs | 900 nm | 2E+18 | Be | p |
| GaAs | 3100 nm | 2E+17 | Si | n |
| Al_{0.2}Ga_{0.8}As | 200 nm | 1E+18 | Si | Back surface field |
| GaAs | 500 nm | 2E+18 | Si | Buffer |
| | | | | n⁺-GaAs substrate |

The use of AlAs (or, more generally, AlₓGa₁₋ₓAs) as a window layer is compatible with both single-junction and multi-junction solar cells. The material is simple to grow. The protection of the window layer from oxidation allows the avoidance of uncertainties and non-uniformities, which in turn allows the more straightforward implementation of an optimised anti-reflection coating.

The use of the window protection layer lifts the generally-accepted restriction on the AlₓGa₁₋ₓAs aluminium fraction, so that the wide bandgap that AlₓGa₁₋ₓAs offers (about 3.0 eV) can be more fully exploited. This allows superior window transmission and superior minority carrier confinement.

The anti-reflection coating performance is also boosted, through the use of low loss materials (including the AlₓGa₁₋ₓAs window), since the anti-reflection coating can be made with higher optical quality. In effect, a flat, clean surface is presented to the AR coating, substantially free of oxide/hydroxide. This is the ideal surface for the deposition of ZnS and MgF₂ materials. Reflection and scattering that would otherwise be expected from oxidised/hydrolysed AlₓGa₁₋ₓAs is therefore avoided.

Known devices tend to degrade over time due to ongoing oxidation of the window layer. The use of the window protection layer substantially reduces such oxidation in service, thereby significantly extending the service life of the device.

Known window materials such as (AlₓGa₁₋ₓ)_{0.51}In_{0.49}P have a relatively low aluminium fraction, and so are relatively robust against oxidation. However, they have inferior bandgap energy (about 1.9<E_{Γ}<2.6 eV) to the preferred window materials used herein, resulting in increased absorption of useful photons in the window and in decreased minority carrier confinement. Furthermore, these materials are complex to grow ((AlₓGa₁₋ₓ)_{0.51}In_{0.49}P is a quaternary system), and may result in poorer interfaces and increased risk of surface recombination.

### Demonstration of Effects of Window Protection Layer

In order that the skilled person may even more readily understand the effectiveness of the embodiments of the present invention, it is instructive to compare the technical properties of devices with and without a window protection layer.

In the following discussion, the layers over the p-type GaAs layer in a solar cell device according to an embodiment of the invention were as follows (moving upwards through the device from the p-type GaAs towards the contact layer): 30 nm p-Al_{0.9}Ga_{0.1}As (window layer); 2.5-5.0 nm Be⁺-GaAs (window protection layer); 2.0 nm Be⁺—AlAs (etch stop layer); 2 ML un-GaAs; 300 nm Be⁺⁺—GaAs (contact layer). As has been described above, the GaAs protective layer reduces or inhibits AlGaAs oxidation, allowing the use of high-Al content window layers to reduce absorbance of useful photons. The etch stop layer allows the layers above the p-type GaAs layer to have precisely known thickness after etching using wet chemistry techniques. This allows for predictable performance from the dual-layer antireflective coating (ARC) system.

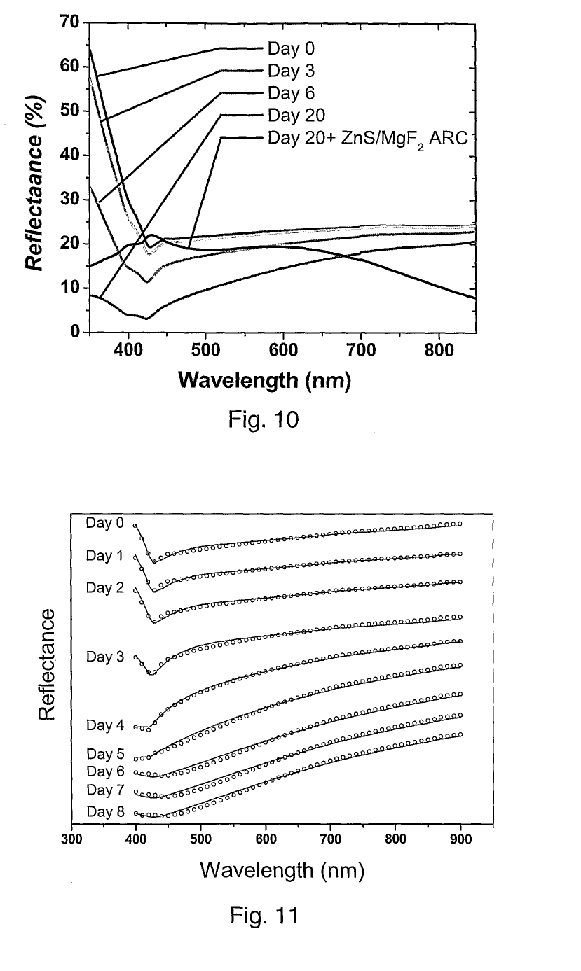

FIG. 10 shows reflection spectra for a device with an AlGaAs window layer but with no window protection layer, the spectra measured over a period of 20 days. Also shown is the day 20 spectrum for a corresponding device with an anti-reflection coating. As can be seen, the reflectance spectra change markedly between days 0 and 20. This is considered to be due to the formation of an oxide layer on the Al_{0.9}Ga_{0.1}As window layer and the subsequent unpredictable change in surface optical qualities and poor ARC performance.

FIG. 11 shows the results from an analysis of the reflection spectra measured over an 8-day period for an unprotected Al_{0.9}Ga_{0.1}As window layer. The lines show fitting using a multi-layer model. The significant change in behaviour is considered to be due to the formation of an inhomogenous oxide layer on the Al_{0.9}Ga_{0.1}As window layer with a porous surface.

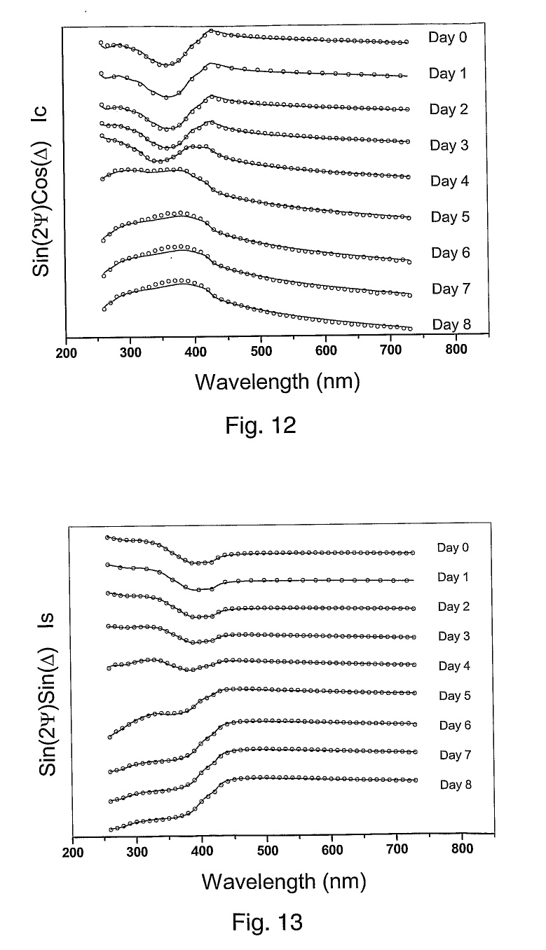

FIGS. 12 and 13 show spectroscopic ellipsometry measurements over an 8-day period for an unprotected Al_{0.9}Ga_{0.1}As window layer. The lines show fitting using a multi-layer model.

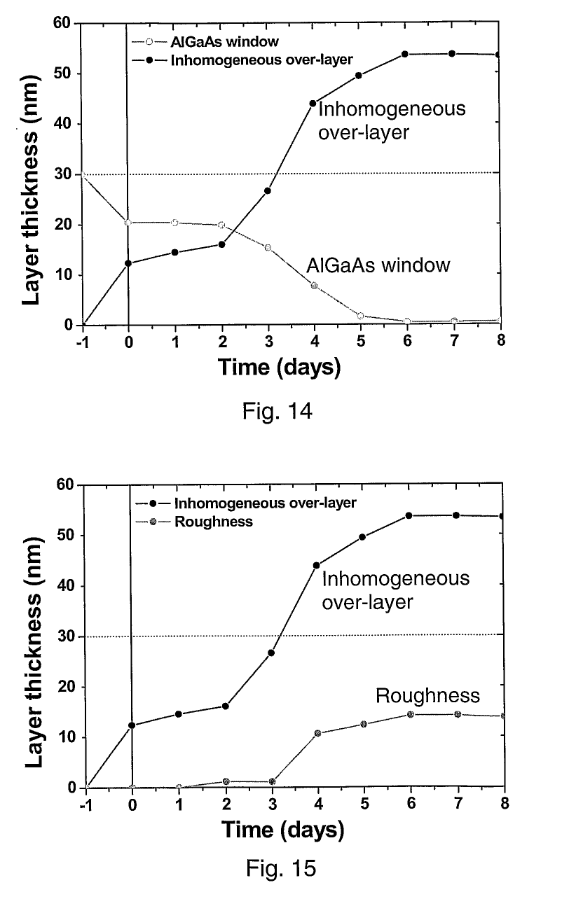

FIGS. 14 and 15 show the results of a multi-layer model fit of the evolution of degradation of an unprotected Al_{0.9}Ga_{0.1}As window layer. A rough oxide-like inhomogeneous layer grows, consuming AlGaAs. Optical scattering due to roughness is apparent to the naked eye by day 4. A roughness parameter (see FIG. 15) is required in the fit.

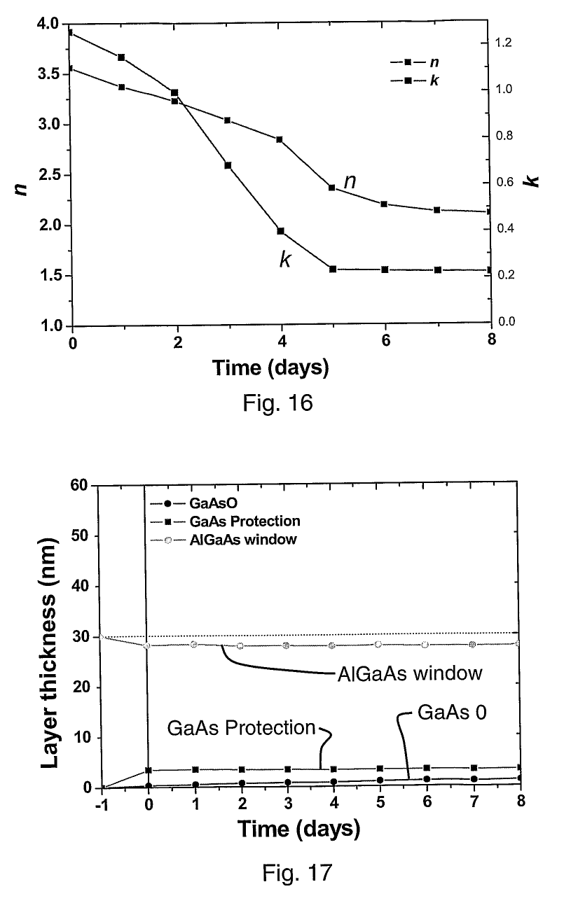

FIG. 16 shows the variation of refractive index (n) and extinction coefficient (k) at a wavelength of 400 nm for an unprotected Al_{0.9}Ga_{0.1}As window layer. The fitted optical constants of the layer indicate a transition from semiconductor-like to oxide-like refractive index and extinction coefficient.

FIG. 17 shows the results of a multi-layer model fit on the stability of the layer thickness for a protected Al_{0.9}Ga_{0.1}As window layer according to this embodiment of the invention. This shows the stability against air-exposure of the device.

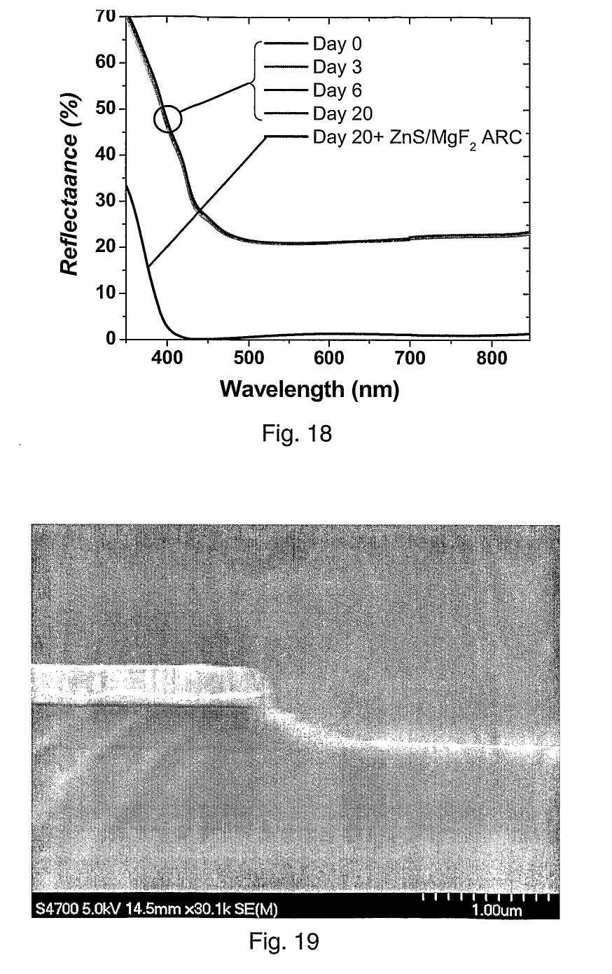

FIG. 18 shows reflection spectra for a device with a protected Al_{0.9}Ga_{0.1}As window layer according to this embodiment of the invention. The spectra were measured over a period of 20 days. Also shown is the day 20 spectrum for a corresponding device with an anti-reflection coating. As can be seen, there was very little variation in the reflection spectra with time. After deposition of the ARC (ZnS/MgF₂), the device showed low reflectivity.

### Demonstration of Effects of Etch Stop Layer

The objectives of this evaluation were to demonstrate the utility and performance of etch stop layers in embodiments of the present invention, and particularly to evaluate:
(i) whether the etch-stop with ‘protected window’ results in a predictable etch depth and in a smooth semiconductor surface,
(ii) whether the etch-stop process provides a wide processing window, and
(iii) whether undercut of the mask is prohibitive.

The epitaxial layer structures were as shown in Tables 7 and 8.

TABLE 7
(Sample A2214) Epitaxial structure for comparison,
without etch-stop and protection layers, grown by MBE.

| Composition and thickness | Description |
|---|---|
| 300 nm GaAs | cap layer |
| 30 nm Al_{0.9}Ga_{0.1}As | window layer |
| | GaAs buffer layer |

TABLE 8
(Sample A2217) Epitaxial structure with separate
etch-stop and protection layers, grown by MBE.

| Composition and thickness | Description |
|---|---|
| 300 nm GaAs | cap layer |
| 2 nm AlAs | etch-stop layer |
| 5 nm GaAs | protection layer |
| 30 nm Al_{0.9}Ga_{0.1}As | window layer |
| | GaAs buffer layer |

Five samples were taken from wafer growth A2217 and patterned (solar cell grid pattern) with photoresist by standard photolithography techniques. Each piece was etched using the following procedure:
(i) native oxide removal in dilute HCl acid, followed by a rinse in de-ionised water,
(ii) selective etching of the GaAs cap layer in citric acid:H₂O₂ (5:1) solution,
(iii) selective etching of the etch-stop layer in dilute HCl acid,
   where the time spent in citric acid:H₂O₂ (5:1) solution was varied. The photoresist was removed in acetone and each sample was then measured using an Atomic Force Microscope (AFM) to determine the height of the etched step and the surface roughness of the etched material.

As a reference, a sample from A2214 with no window protection and etch stop layers was processed and measured.

The results of the investigation are set out in Table 9.

TABLE 9
Results of selective etch tests.

| | Citric acid | Step Height | Roughness | Roughness |
|---|---|---|---|---|
| Sample | etch time | (ash) | (RMS) | (Rₘₐₓ₎ |
| A | 30 s | 165.6 nm | 0.334 nm | 2.479 nm |
| B | 75 s | 304.0 nm | 0.273 nm | 1.618 nm |
| C | 120 s | 301.5 nm | 0.261 nm | 2.43 nm |
| D | 600 s | 334 nm | 0.973 nm | 6.161 nm |
| E | 1200 s | 343 nm | 0.267 nm | 2.648 nm |

As a reference, a sample from A2214 with no window layer was processed and measured (Table 10).

TABLE 10
Results of selective etch tests on reference sample.

| | | | Roughness | Roughness |
|---|---|---|---|---|
| Sample | Etch time | Step Height | (RMS) | (Rmax) |
| 1 | 120 s | — | 0.26 nm | 3.120 nm |
| 2 | 600 s | — | 0.373 nm | 3.126 nm |

Sample A was etched for a time less than that required to fully remove the GaAs layer. The roughness of the etched surface will be the equivalent of having a fixed time etch through a GaAs layer.

Sample B was etched to clear the GaAs layer with no significant over etch. In this case it is seen that the etch has stopped on the AlAs layer as expected with a roughness better than a timed GaAs etch (A).

Sample C was etched for a time which allowed clearing of the GaAs layer plus some over etch. Again it is seen that the etch had stopped on the AlAs etch-stop layer and that roughness is better than (A).

Sample D was etched for 10 minutes with the intention of finding out when the etch-stop is compromised. In this case it appears that the etch stop was breached during the citric acid:H₂O₂ etching and that the GaAs protective layer was removed before the final dilute HCl etch was performed (which attacks the AlGaAs window layer). Roughness is slightly worse that that seen where the etch stop remained intact.

Sample E was etched for 20 minutes. Again, it is clear that the etch stop was breached during the citric acid:H₂O₂ etching and that the GaAs protective layer was removed before the final dilute HCl etch was performed. As the GaAs buffer layer acted as an etch stop during the final dilute HCl etch, the surface roughness is comparable to C.

Two samples from piece A2214 were etched as a reference. This sample had no dedicated etch stop layer (nor protection layer of any kind) and it was expected that the selective citric acid:H₂O₂ etch would ‘stop’ somewhere on/in the AlGaAs window layer. It can be seen that the results are comparable with sample E.

The results above show that the etch stop layer functions as expected and provides a means of forming a protection layer over the window layer with low surface roughness. The etch stop is capable of resisting over-etching, providing a wide processing window.

Selective etching of the cap layer was carried out using an ohmic contact as an etch mask. A piece of A2217 was processed using a lift-off process to form a patterned p-ohmic metal (Ti—Pd—Au-based) etch mask. This metal pattern was annealed using the RTA at 360° C. and subjected to the same etch process as used for the etch tests above, but with a fixed citric acid:H₂O₂ etch time of 120 seconds.

The SEM micrograph of FIG. 19 shows an isolated five micron metal line after etching. In the SEM image, the dark line formed by the AlGaAs layer can be seen, and the cap etch terminated above the AlGaAs layer at the etch-stop. It is seen that there was no undercut of the metal finger.

Thus, the etch stop layer works effectively and provides sufficient process latitude to be used in manufacturing.

The embodiments above have been described by way of example. On reading this disclosure, modifications of these embodiments, further embodiments and modifications thereof will be apparent to the skilled person and as such are within the scope of the present invention.

### LIST OF REFERENCES

1 I. Vurgaftma, Meyer, J. R., Ram-Mohan, L. R., “Band parameters for III-V compound semiconductors and their alloys”, J. Appl. Phys., 89 (11), 2001.
2 Bode, M. H., Ourmazd, A., ‘Interfaces in GaAs/AlAs—Perfection and applications’, Journal Of Vacuum Science & Technology B, 10 (4), pp. 1787-1792, 1992.
3 Bimberg, D., Heinrichsdorff, F., Bauer, R. K., ‘Binary AlAs/GaAs versus ternary GaAlAs/GaAs interfaces—A dramatic difference of perfection’, Journal Of Vacuum Science & Technology B, 10 (4), pp. 1793-1798, 1992.
4 Bocchi, C., Ferrari, C., Franzosi, P., Bosacchi, A., Franchi, S., ‘Accurate determination of lattice mismatch in the epitaxial AlAs/GaAs system by high-resolution X-ray diffraction’, Journal of Crystal Growth, 132 (3-4), pp. 427-434, 1993.
5 Handbook of Optical Constants of Solids II, E. D. Palik, Ed, Academic Press, Orlando London, 1991.
6 Dallesasse, J. M., Holonyak, N., Jr., Sugg, A. R., Richard, T. A., El-Zein, N., ‘Hydrolyzation oxidation of AlₓGa₁₋ₓAs—AlAs—GaAs quantum well heterostructures and superlattices’, Appl. Phys. Lett., 57 (26), pp. 2844-2846, 1990.
7J. M. Dallesasse, P. Gavrilovic, N. Holonyak, Jr., R. W. Kaliski, D. W. Nam, E. J. Vesely, and R. D. Burnham, ‘Stability of AlAs in AlₓGa₁₋ₓAs—AlAs—GaAs quantum well heterostructures’, Appl. Phys. Lett., 56 (24), p. 2436-2438, 1990.
8 J. M. Dallesasse, N. El-Zein, N. Holonyak, Jr., K. C. Hsieh, R. D. Burnham, and R. D. Dupuis, ‘Environmental degradation of AlₓGa₁₋ₓAs—GaAs quantum-well heterostructures’, J. Appl. Phys., 68 (5), pp. 2235-2238, 1990.
9 C. Algora del Valle, C. Alcaraz, M. F., ‘Performance of antireflecting coating-A1GaAs window layer coupling for terrestrial concentrator GaAs solar cells’, IEEE Trans. Electron. Dev., 44 (9), pp. 1499-1506, 1997.
10 Rey-stolle, I., Algora, C., ‘Optimum Antireflection Coatings for Heteroface A1GaAs/GaAs Solar Cells—Part I: The Influence of Window Layer Oxidation’, Journal of Electronic Materials, 29 (7), pp. 984-991, 2000.
11 Rey-stolle, I., Algora, C., ‘Optimum antireflection coatings for heteroface AlGaAs/GaAs solar cells: Part II: The influence of uncertainties in the parameters of window and antireflection coatings’, Journal of Electronic Materials, 29 (7), pp. 992-999, 2000.
12 van Riesen, S., Bett, A. W., ‘Degradation study of III-V solar cells for concentrator applications’, Progress in Photovoltaics: Research and Applications, 13 (5), pp. 369-380, 2005.
13 M. Tong, D. G. Ballegeer, A. Ketterson, E. J. Roan, K. Y. Cheng, and I. Adesida, “A Comparative-Study Of Wet And Dry Selective Etching Processes For GaAs AlGaAs InGaAs Pseudomorphic MODFETs”, J. Electron. Mater. 21(9), 1992.
14 Carter-Coman C., Bicknell-Tassius R., Benz R. G., Brown A. S., Jokerst N. M., “Analysis of GaAs substrate removal etching with citric acid:H₂O₂ and NH₄OH:H₂O₂ for application to compliant substrates”, Journal of the Electrochemical Society, 144 (2): L29-L31, FEB 1997.
15 Chang E Y, Lai Y L, Lee Y S, Chen S H, “A GaAs/AlAs wet selective etch process for the gate recess of GaAs power metal-semiconductor field-effect transistors”, Journal Of The Electrochemical Society, 148(1), pp G4-G9, 2001.
16 Grundbacher R, Chang H, Hannan M, Adesida I, “Fabrication Of Parallel Quantum Wires In GaAs/AlGaAs Heterostructures Using AlAs Etch-Stop Layers”, Journal Of Vacuum Science & Technology B, 11 (6), pp. 2254-2257, 1993.
17 Broekaert, T. P. E., Fonstad, C. G., ‘AlAs etch-stop layers for InGaAlAs/InP heterostructure devices and circuits’, IEEE Transactions on Electron Devices, 39 (3), pp. 533-536, 1992.
18 Sanfacon, M. M., Tobin, S. P., ‘Analysis of AlGaAs/GaAs solar cell structures by optical reflectance spectroscopy’, IEEE Transactions on Electron Devices, 37 (2), pp. 450-454, 1990.
19 The Concise MacLeod, Version 8.0b, Copyright © Thin Film Center Inc 1997-2000. Thin Film Center Inc., 2745 E Via Rotonda, Tucson Ariz. 85716.
20 F. Lukes, ‘Oxidation of Si and GaAs in air at room-temperature’, Surface Science, 30 (1), pp. 91-100, 1972.
21 DeSalvo G. C., Bozada C. A., Ebel J. L., Look D. C., Barrette J. P., Cerny C. L. A., Dettmer R. W., Gillespie J. K., Havasy O. K., Jenkins T. J., Nakano K., Pettiford C. I., Quach T. K., Sewell J. S., Via G. D., ‘Wet chemical digital etching of GaAs at room temperature’, Journal of the Electrochemical Society, 143 (11), pp. 3652-3656, 1996.
22 NOTE: In a compound semiconductor such as GaAs, a monolayer refers to the distance between two planes of Ga atoms. For growth on a (100) GaAs surface 1 ML=a₀/2, where a₀=0.56536 nm is the lattice parameter for GaAs.
23 Burstein, E., ‘Anomalous Optical Absorption Limit in InSb’, Phys. Rev., 93, pp. 632-633, 1954.
24 Kim, J., Lim, D. H., Yang, G. M., ‘Selective etching of AlGaAs/GaAs structures using the solutions of citric acid/H₂O₂ and de-ionized H₂O/buffered oxide etch’, J. Vac. Sci. Technol. B, 16(2), p. 558, 1998.
25 DeSalvo, G. C., Tseng, W. F., Comas, J., ‘Etch Rates and Selectivities of Citric Acid/Hydrogen Peroxide on GaAs, AlGaAs, InGaAs, InAlAs, and InP’, Journal of the Electrochemical Society, 139 (3), pp. 831-835, 1992.
26 Chin-I Liao, Po-Wen Sze, Mau-Phon Houng, Yeong-Her Wang, ‘Very High Selective Etching of GaAs/Al_{0.2}Ga_{0.8}As for Gate Recess Process to Pseudomorphic High Electron Mobility Transistors (PHEMT) Applications Using Citric Buffer Solution’, Japanese Journal of Applied Physics, 43 (6B), pp. L800-L802, 2004.
27 Clawson, A. R., ‘Guide to references on III-V semiconductor chemical etching’, Materials Science and Engineering, 31, pp. 1-438, 2001.
28 Chin-I. Liao, Mau-Phon Houng, Yeong-Her Wang, ‘Highly Selective Etching of GaAs on Al_{0.2}Ga_{0.8}As Using Citric Acid/H₂O₂/H₂O Etching System’, Electrochem. Solid-State Lett., 7 (11), pp. C129-C132, 2004.
29 Zhao, R., Lau, W. S., Chong, T. C., Li, M. F., ‘A comparison of the selective etching characteristics of conventional and low-temperature-grown GaAs over AlAs by various etching solutions’, Japanese Journal of Applied Physics, 35 (1A), pp. 22-25, 1996.
30 Kasahara, K., Ohkubo, S., Ohno, Y., ‘Layer selective anisotropic wet etching with a cooled citric acid/H₂O₂ solution for high performance GaAs HJFETs’, Compound Semiconductors 1996. Proceedings of the Twenty-Third International Symposium on Compound Semiconductors, (115), pp. 507-510, 1997.
31 Chang, E. Y., Lai, Y. L., Lee, Y. S., ‘A GaAs/AlAs wet selective etch process for the gate recess of GaAs power metal-semiconductor field-effect transistors’, Journal of the Electrochemical Society, 148 (1), pp. G4-G9, 2001
32 Hue, X., Boudart, B., Crosnier, Y., ‘Gate recessing optimization of GaAs/Al_{0.22}Ga_{0.78}As heterojunction field effect transistor using citric acid hydrogen peroxide ammonium hydroxide for power applications’, Journal Of Vacuum Science & Technology B, 16 (5), pp. 2675-2679, 1998.
33 Shigyo, K., Umemura, S., Kawase, K., ‘Chemical etching behavior and mechanism of undoped GaAs in tartaric acid—hydrogen peroxide solution systems’, Electrochemistry 72 (6), pp. 466-470, 2004.
34 Pearton, S. J., ‘Critical issues of III-V compound semiconductor processing’, Materials Science and Engineering B, 44 (1-3), pp. 1-7, 1997.
35 Wu, X. S., Coldren, L. A., Merz, J. L., ‘SELECTIVE ETCHING CHARACTERISTICS OF HF FOR AL_{X}GA_{1-X}AS/GAAS’, Electronics Letters, 21(13), pp. 558-559, 1985.
36 United States Patent Application Publication, US 2003/0145884 A1, ‘Wide-bandgap, lattice-mismatched window layer for solar conversion device’, Aug. 7, 2003.
37 Milanova M, Mintairov A, Rumyantsev V, Smekalin K., ‘Spectral characteristic of GaAs solar cells grown by LPE’, Journal of Electronic Materials; 28 (1), pp. 35-38, 1999.
38 van Riesen, S., Schubert, U., Bett A. W., ‘GaAs photovoltaic cells for laser power beaming at high power densities’ Proceedings of the 17th European Photovoltaic Solar Energy Conference, Munich, 2001; pp. 182-185.

1. A semiconductor-based optoelectronic device having an n-type layer and a p-type layer, together forming a p-n junction, the device further including:
at least one contact region;
at least one light-receiving or light-transmitting region;
a window layer formed over the n-type layer or the p-type layer, at least at said light-receiving or light-transmitting region, the window layer providing, in operation, at least partial transmission of incident or generated light through to or from the n-type layer or p-type layer, and promoting reduced carrier recombination at the surface of the n-type or p-type layer, and/or at least partial reflection of minority carriers in the n-type or p-type layer towards the p-n junction,
wherein the device has a window protection layer formed over the window layer, the window protection layer providing protection from degradation of the window layer during manufacture and/or operation of the device.

2. A device according to claim 1 wherein the window protection layer provides protection against degradation by oxidation and/or hydrolysis of the window layer.

3. A device according to claim 1 wherein the device further includes an anti-reflection coating formed at least at said light receiving region, the anti-reflection coating being formed over the window protection layer.

4. A device according to claim 1 wherein the thickness of the window layer is at least 5 nm.

5. A device according to claim 1 wherein the thickness of the window layer is at most 1.5 μm.

6. A device according to claim 1 wherein the thickness of the window protection layer is at least 1 ML.

7. A device according to claim 1 wherein the thickness of the window protection layer is at most 0.5 μm.

8. A device according to claim 1 wherein the contact region includes a layer of semiconducting contact material formed over the window protection layer, with an etch-stop layer sandwiched between the layer of semiconducting contact material and window protection layer.

9. A device according to claim 8 wherein the etch-stop layer is formed of a material having an etching rate of at least 10 times slower than an etching rate of the semiconducting contact material under the same predetermined etchant conditions.

10. A device according to claim 8 wherein the etch stop layer comprises group III-V semiconducting material.

11. A device according to claim 8 wherein the etch stop layer comprises AlₓGa₁₋ₓAs.

12. A device according to claim 8 wherein the etch stop layer comprises AlAs.

13. A device according to claim 8 wherein the etch-stop layer has a thickness of at most 10 nm.

14. A device according to claim 8 wherein the thickness of the semiconducting contact material layer is at least 5 nm.

15. A device according to claim 1 wherein the device includes a substrate and the n-type and p-type layers are epitaxial layers, the device optionally including intermediate layers between the substrate and the n-type or p-type layers.

16. A device according to claim 1 wherein the n-type layer and p-type layer are each based on group III-V semiconducting material.

17. A device according to claim 16 wherein the III-V group semiconducting material is Ga—As based material.

18. A device according to claim 1 wherein In is substantially absent from the window layer.

19. A device according to claim 1 wherein the window layer comprises AlₓGa₁₋ₓAs in which x is greater than 0 and at most 1.

20. A device according to claim 19 wherein x is at least 0.5.

21. A device according to claim 19 wherein x is at least 0.85.

22. A device according to claim 1 wherein a band gap energy at the Γ-point of the window layer is at least 2.7 eV.

23. A device according to claim 1 wherein a band gap energy of the window protection layer is at most 2.6 eV.

24. A device according to claim 1 wherein the window protection layer comprises Ga—As based material.

25. A device according to claim 1 wherein the window protection layer comprises GaAs.

26. A device according to claim 1 wherein the optoelectronic device is a photovoltaic device.

27. A semiconductor-based optoelectronic device having an n-type layer and a p-type layer, together forming a p-n junction, the device further including:
at least one contact region;
at least one light-receiving or light-transmitting region;
a window layer formed over the n-type layer or the p-type layer, at least at said light-receiving or light-transmitting region, the window layer providing, in operation, at least partial transmission of incident or generated light through to or from the n-type layer or p-type layer, and promoting reduced carrier recombination at the surface of the n-type or p-type layer, and/or at least partial reflection of minority carriers in the n-type or p-type layer towards the p-n junction,
wherein the contact region includes a layer of semiconducting contact material, with an etch-stop layer sandwiched between the semiconducting contact material and the window layer.

28. A method of manufacturing a semiconductor-based optoelectronic device, the device having an n-type layer and a p-type layer, together forming a p-n junction, the method including the steps:
forming a window layer over the n-type layer or the p-type layer;
forming a window protection layer over the window layer;
optionally, forming an etch-stop layer over the window protection layer;
forming a layer of semiconducting contact material over the window protection layer or over the etch-stop layer, if present;
etching the layer of semiconducting contact material under a semiconducting contact material etching condition in at least one region corresponding to a light-receiving or light-transmitting region of the final device, to leave at least one light-receiving or light-transmitting region and at least one contact region, the etching stopping at the window protection layer or at the etch-stop layer, if present; and
optionally, removing the etch-stop layer, if present, at least from the light-receiving or light-transmitting region.

29. A method according to claim 28 wherein the window protection layer or the etch-stop layer has an etching rate under said semiconducting contact material etching condition of at least 10 times slower than the semiconductor contact material.

30. A method according to claim 28 wherein the semiconducting contact material etching condition includes the use of an etchant comprising an oxidising agent for oxidising the semiconducting contact material and an agent for dissolving the oxidised semiconducting contact material.

31. A method according to claim 30 wherein the etchant is selected from the group consisting of:
(a) citric acid:hydrogen peroxide (C₆H₈O₇:H₂O₂) solution;
(b) C₆H₈O₇(citric acid):K₃C₆H_{S}O₇ (potassium citrate):H₂O₂-based;
(c) C₆H₈O₇(citric acid):NH₄OH:H₂O₂-based;
(d) C₄H₆O₄(succinic acid):H₂O₂-based, optionally pH-adjusted;
(e) C₄H₆O₆(tartaric acid)-based;
(f) C₂H₂O₄(oxalic acid)-based;
(g) NH₄OH:H₂O₂-based, pH-adjusted; and
(h) HF-, HCl-, H₂SO₄-, R₃PO₄-, HNO₃-, HI-, H₃PO₂-, or NH₄OH-based solution.

32. A method according to claim 28 wherein the etch-stop layer is removed under an etch-stop layer etching condition, different from the semiconducting contact material etching condition.

33. A method according to claim 28 including subsequently forming an antireflective coating over at least the light-receiving or light-transmitting region.

34. A method of manufacturing a semiconductor-based photovoltaic device, the device having an n-type layer and a p-type layer, together forming a p-n junction, the method including the steps:
forming a window layer over the n-type layer or the p-type layer;
optionally, forming a window protection layer over the window layer;
forming an etch-stop layer over the window layer, or over the window protection layer, if present;
forming a layer of semiconducting contact material over the etch-stop layer;
etching the layer of semiconducting contact material under a semiconducting contact material etching condition in at least one region corresponding to a light-receiving or light-transmitting region of the final device, to leave at least one light-receiving or light-transmitting region and at least one contact region, the etching stopping at the etch-stop layer; and
optionally, removing the etch-stop layer at least from the light-receiving region.

35. A method according to claim 34 including subsequently forming an anti-reflective coating over at least the light-receiving or light-transmitting region.
